(19) United States
(12) Patent Application Publication
(10) Pub. No.: US 2025/0184586 A1
(43) Pub. Date: Jun. 5, 2025

(54) IMAGING ELEMENT UNIT AND IMAGING APPARATUS

(71) Applicant: FUJIFILM Corporation, Tokyo (JP)

(72) Inventors: Motomu SHIBASAKI, Saitama-shi (JP); Kouhei AWAZU, Saitama-shi (JP); Takuro ABE, Saitama-shi (JP); Yuta ABE, Saitama-shi (JP); Yuta WATANABE, Saitama-shi (JP)

(73) Assignee: FUJIFILM Corporation, Tokyo (JP)

(21) Appl. No.: 19/050,122

(22) Filed: Feb. 11, 2025

Related U.S. Application Data
(63) Continuation of application No. PCT/JP2023/029473, filed on Aug. 14, 2023.

(30) Foreign Application Priority Data
Aug. 23, 2022 (JP) 2022-132811

(51) Int. Cl. H04N 23/52; G03B 17/55; H04N 23/51; H04N 23/54; H04N 23/68

(52) U.S. Cl. CPC H04N 23/52; G03B 17/55; H04N 23/51; H04N 23/54; H04N 23/687

(57) ABSTRACT

An imaging element unit is built in a housing of an imaging apparatus, and includes an imaging element that includes an imaging surface for imaging a subject, an anti-vibration function to move the imaging element in plane directions of the imaging surface, and a thermally conductive member to which heat of the imaging element is conducted and which includes a bent portion to be deformed to be capable of following movement of the imaging element caused by the anti-vibration function and an unbent portion other than the bent portion. Structures of the bent portion and the unbent portion are different from each other.

### CROSS-REFERENCE TO RELATED APPLICATIONS

This application is a continuation application of International Application No. PCT/JP2023/029473 filed on Aug. 14, 2023, the disclosure of which is incorporated herein by reference in its entirety. Further, this application claims priority from Japanese Patent Application No. 2022-132811 filed on Aug. 23, 2022, the disclosure of which is incorporated herein by reference in its entirety.

### BACKGROUND

### 1. Technical Field

A technique of the present disclosure relates to an imaging element unit and an imaging apparatus.

### 2. Description of the Related Art

WO2020/202811A discloses an image shake correction device comprising a stationary body that is fixed inside an outer casing, a movable body that includes an imaging element and is moved relative to the stationary body in a direction orthogonal to an optical axis direction, and a heat transfer sheet. The heat transfer sheet is a bendable sheet of which a part is mounted on each of the stationary body and the movable body and which transfers heat generated in the movable body to the stationary body. A thickness direction of the heat transfer sheet is a direction orthogonal to the optical axis direction.

### SUMMARY

One embodiment according to the technique of the present disclosure provides an imaging element unit and an imaging apparatus in which a thermally conductive member to which heat of an imaging element is conducted and which is deformed to be capable of following movement of the imaging element caused by an anti-vibration function can be adapted to have a suitable structure.

An imaging element unit according to an aspect of the present disclosure is an imaging element unit that is built in a housing of an imaging apparatus, and comprises an imaging element that includes an imaging surface for imaging a subject, an anti-vibration function to move the imaging element in plane directions of the imaging surface, and a thermally conductive member to which heat of the imaging element is conducted and which includes a bent portion to be deformed to be capable of following movement of the imaging element caused by the anti-vibration function and an unbent portion other than the bent portion, in which structures of the bent portion and the unbent portion are different from each other.

It is preferable that the bent portion has a structure of which mechanical strength is higher than mechanical strength of the unbent portion.

It is preferable that the thermally conductive member includes a thermally conductive material and a coating material that coats the thermally conductive material and is wider than the thermally conductive material, and a coating margin, which is a distance between an end portion of the thermally conductive material in a width direction and an end portion of the coating material in the width direction, is larger at the bent portion than at the unbent portion.

It is preferable that a width of the thermally conductive material is smaller at the bent portion than at the unbent portion. In this case, it is preferable that a width of the coating material is the same at the bent portion and the unbent portion.

It is preferable that a width of the coating material is larger at the bent portion than at the unbent portion. In this case, it is preferable that a width of the thermally conductive material is the same at the bent portion and the unbent portion.

It is preferable that the thermally conductive member is disposed at a position facing a circuit board of the imaging element, and a thickness of the circuit board at a position facing the bent portion is smaller than a thickness of the circuit board at a position facing the unbent portion.

It is preferable that the bent portion has a structure that reduces resistance to bending. It is preferable that a slit is formed at the bent portion.

It is preferable that a longitudinal direction of the slit is along a direction in which the thermally conductive member expands and contracts due to bending of the bent portion.

It is preferable that thermally conductive layers including a thermally conductive material are laminated in the thermally conductive member, and the thermally conductive layers are not adhered to each other at the bent portion and are adhered to each other at the unbent portion.

It is preferable that the bent portion is thinner than the unbent portion.

It is preferable that at least the bent portion includes thermally conductive layers including a thermally conductive material, thermally conductive layers including a thermally conductive material are laminated in at least the unbent portion, and the number of the thermally conductive layers laminated in the unbent portion is larger than the number of the thermally conductive layers laminated in the bent portion.

An imaging apparatus according to another aspect of the present disclosure comprises a housing and the above-described imaging element unit that is built in the housing.

### BRIEF DESCRIPTION OF THE DRAWINGS

Exemplary embodiments according to the technique of the present disclosure will be described in detail based on the following figures, wherein:

FIG. 1 is a diagram showing a digital camera;

FIG. 2 is a front exploded perspective view of an imaging element unit;

FIG. 3 is a rear exploded perspective view of the imaging element unit;

FIG. 4 is a rear exploded perspective view of a main part of the imaging element unit;

FIG. 5 is a diagram showing a configuration of a thermally conductive member;

FIG. 6 is a perspective view of thermally conductive members;

FIG. 7 is a plan view of the thermally conductive members;

FIG. 8 is a perspective view of a reinforcing member;

FIG. 9 is a diagram showing a vicinity of a member connecting portion;

FIG. 10 is a perspective view of thermally conductive members and connecting members;

FIG. 11 is a simple plan view of the thermally conductive member;

FIG. 12 is a diagram showing a state where a material of the thermally conductive member is not yet bent and a state where the material of the thermally conductive member has been bent;

FIG. 13 is a diagram showing thicknesses of a bent portion and an unbent portion;

FIG. 14 is a diagram showing an aspect in which the thermally conductive member is deformed;

FIG. 15 is a diagram showing an aspect in which the thermally conductive member is deformed;

FIG. 16 is a diagram showing a conduction path of the heat of the imaging element;

FIG. 17 is a view showing a thermally conductive member that includes only an outer layer portion;

FIG. 18 is a view showing a thermally conductive member having a triple-layer structure;

FIG. 19 is a view showing an octagonal thermally conductive member;

FIG. 20 is a diagram showing a thermally conductive member in which corners of connecting portions of an outer layer portion and corners of connecting portions of an inner layer portion are recessed inward;

FIG. 21 is a diagram showing an example in which the thermally conductive member is connected to a central region of a back surface of a circuit board including no opening;

FIG. 22 is a diagram showing a thermally conductive member of a second embodiment in which a bending angle of a bent portion of an inner layer portion is smaller than a bending angle of a bent portion of an outer layer portion;

FIG. 23 is a diagram showing a thermally conductive member of a third embodiment comprising an outer layer portion that has a structure of which thermal conductivity is higher than that of an inner layer portion and an inner layer portion that has a structure of which mobility is higher than that of the outer layer portion;

FIG. 24 is a diagram showing the vicinity of a bent portion of the thermally conductive member shown in FIG. 23;

FIG. 25 is a diagram showing a thermally conductive member of a fourth embodiment in which a plurality of thermally conductive layers are laminated;

FIG. 26 is a diagram showing a state where a material of the thermally conductive member shown in FIG. 25 is not yet bent;

FIG. 27 is a diagram showing a procedure for bending the material of the thermally conductive member shown in FIG. 25;

FIG. 28 is a diagram showing a way in which heat is transmitted in a case where connecting portions are not provided;

FIG. 29 is a diagram showing a way in which heat is transmitted in a case where connecting portions are provided, and is a diagram illustrating an effect of the connecting portions;

FIG. 30 is a diagram showing another example of the thermally conductive member in which a plurality of thermally conductive layers are laminated;

FIG. 31 is a diagram showing an imaging element unit according to a fifth embodiment;

FIG. 32 is a cross-sectional view of the imaging element unit taken along line A-A of FIG. 31 and a cross-sectional view of a main part thereof;

FIG. 33 is a diagram showing a conduction path of the heat of the imaging element of the fifth embodiment;

FIG. 34 is a plan view showing a graphite sheet including graphite in which recessed portions are formed at each bent portion;

FIG. 35 is a perspective view showing a thermally conductive member that is formed through the bending of the graphite sheet including graphite in which recessed portions are formed at each bent portion;

FIG. 36 is a plan view showing a graphite sheet including a resin film in which protruding portions are formed at each bent portion;

FIG. 37 is a perspective view showing a thermally conductive member that is formed through the bending of the graphite sheet including a resin film in which protruding portions are formed at each bent portion;

FIG. 38 is a diagram showing a thickness of a circuit board at a position facing the bent portion and a thickness of the circuit board at a position facing an unbent portion; and

FIG. 39 is a diagram showing a thermally conductive member in which a slit is formed at each bent portion.

### DETAILED DESCRIPTION

An example of an embodiment of a technique of the present disclosure will be described below with reference to the drawings.

### First Embodiment

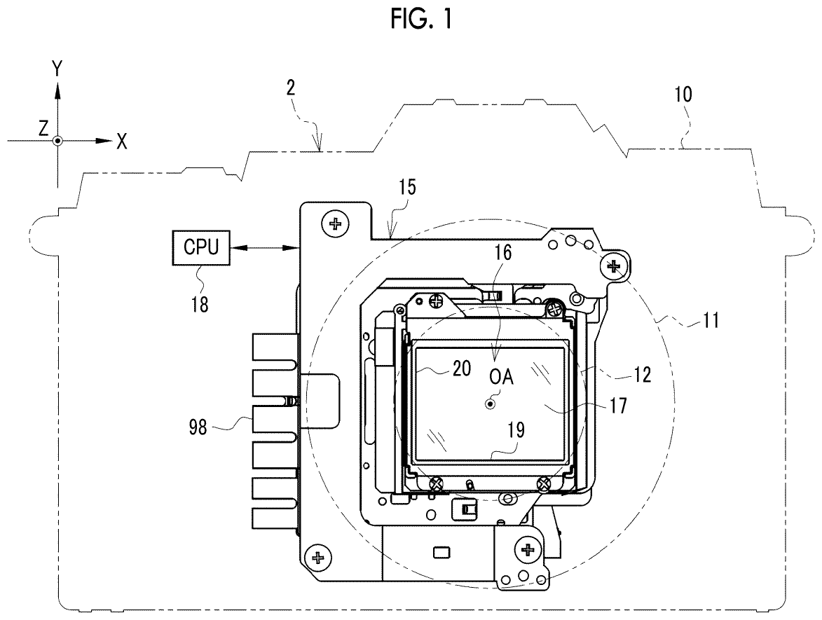

For example, as shown in FIG. 1, a digital camera 2 comprises a camera body 10. A lens mount 11 is provided on a front surface of the camera body 10. The lens mount 11 includes a circular imaging aperture 12. An interchangeable imaging lens (not shown) is attachably and detachably mounted on the lens mount 11. The digital camera 2 is an example of an “imaging apparatus” according to the technique of the present disclosure. Further, the camera body 10 is an example of a “housing” according to the technique of the present disclosure.

An imaging element unit 15 is built in the camera body 10. A rectangular imaging element 16 is mounted on the imaging element unit 15. The imaging element 16 is, for example, a complementary metal oxide semiconductor (CMOS) image sensor or a charge coupled device (CCD) image sensor. The imaging element 16 includes a rectangular imaging surface 17 that images a subject. The imaging surface 17 receives subject light that indicates the subject. As well known, pixels, which photoelectrically convert the received subject light and output electrical signals, are two-dimensionally arranged on the imaging surface 17. The entire imaging surface 17 is exposed to the outside through the imaging aperture 12.

A central processing unit (CPU) 18 is connected to the imaging element unit 15. The CPU 18 controls the operation of the imaging element unit 15. Although not shown, a read only memory (ROM) and/or a random access memory (RAM), which is a memory, is connected to the CPU 18 via a busline. A computer is formed of the CPU 18, the memory, and the bus line.

The imaging element unit 15 has an anti-vibration function. The anti-vibration function is a function to suppress misregistration caused by vibration applied to the camera body 10, that is, relative misregistration between the subject light incident on the imaging surface 17 and the digital camera 2. Examples of the vibration applied to the camera body 10 include a camera shake that is caused by a user who images a subject while holding the camera body 10, and the like.

The imaging element 16 is moved by the anti-vibration function under the control of the CPU 18 in a direction in which misregistration is canceled by a distance that is required to cancel misregistration. More specifically, the imaging element 16 is moved by the anti-vibration function in an X-axis direction that is parallel to a side 19 of the imaging surface 17 of the imaging element 16 and/or a Y-axis direction that is parallel to a side 20 orthogonal to the side 19, that is, intersecting the side 19 at an angle of 90°. The X-axis direction and the Y-axis direction are examples of “plane directions” according to the technique of the present disclosure. Terms related to an angle, such as “orthogonal” and “90°” include not only the meanings of “perfectly orthogonal”, “exact 90°”, and the like but also the meanings of “substantially orthogonal”, “about 90°”, and the like that include an error allowed in design and manufacturing, for example, an error of about ±10% of a design value. Furthermore, the term “parallel” also includes not only the meaning of “perfectly parallel” but also the meaning of “substantially parallel” that includes an error allowed in design and manufacturing, for example, an error of about ±10% of a design value. In the following description, a side corresponding to the side 19 is expressed as “down”, and a side opposite to the side 19 in the Y-axis direction is expressed as “up”. Further, a side corresponding to the side 20 is expressed as “left” and a side opposite to the side 20 in the X-axis direction is expressed as “right”.

Here, “misregistration” in this specification refers to a phenomenon that occurs in a case where the position of an optical axis OA varies with respect to a subject due to vibration. The “optical axis OA” refers to an optical axis of subject light that is incident on the imaging surface 17 through the imaging lens. The variation of the position of the optical axis OA means that the optical axis OA is tilted with respect to a reference axis (for example, an optical axis OA obtained in a case where misregistration does not occur yet) due to misregistration. In this specification, canceling misregistration includes not only the meaning of removing misregistration but also the meaning of reducing misregistration.

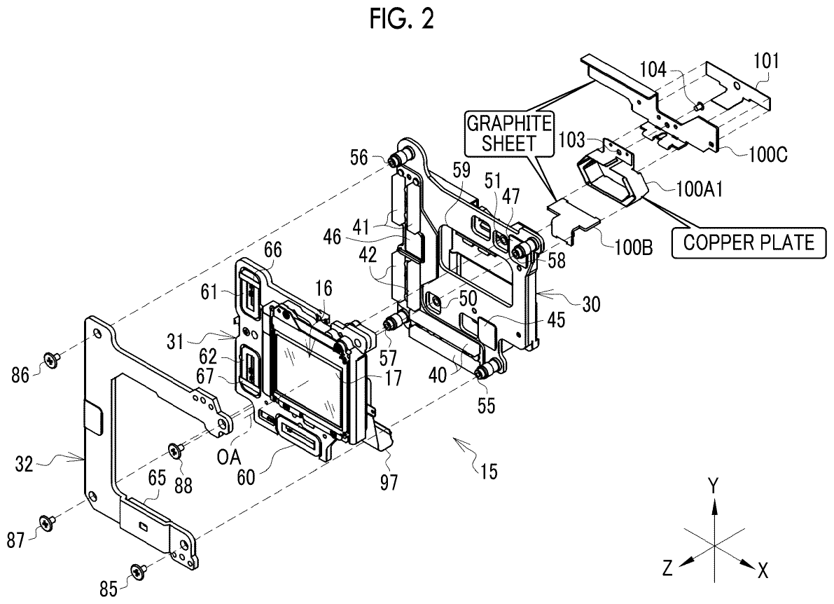

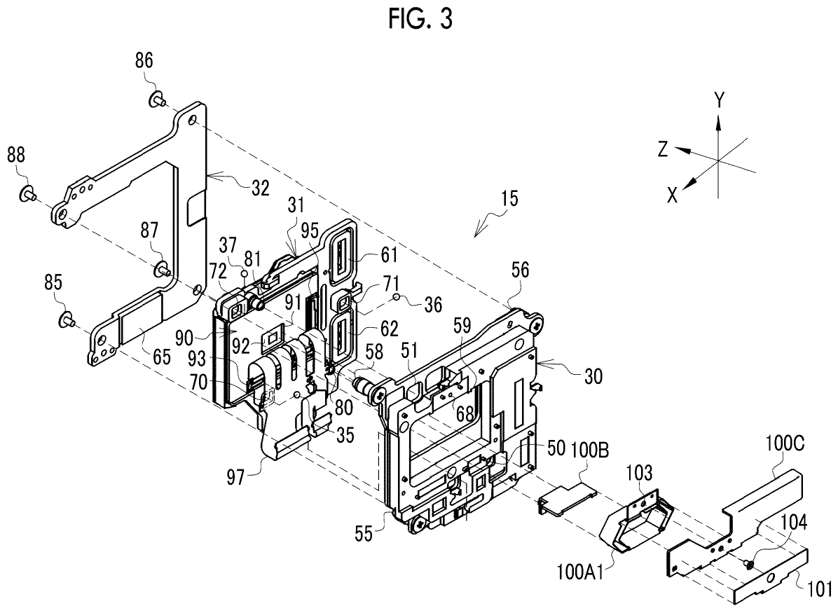

In FIGS. 2 and 3, the imaging element unit 15 comprises a stationary member 30, a movable member 31, a yoke 32, and the like. The stationary member 30 is disposed on a rear side of the camera body 10, and the yoke 32 is disposed on a front side of the camera body 10. The stationary member 30 is fixed to the camera body 10. That is, the position of the stationary member 30 is fixed within the camera body 10. Further, the stationary member 30 and the yoke 32 are fixed to each other with an interval therebetween in a Z-axis direction that is orthogonal to an X axis and a Y axis. The movable member 31 is disposed between the stationary member 30 and the yoke 32 via three balls 35, 36, and 37 having the same size. The movable member 31 can be moved relative to the stationary member 30 and the yoke 32 in the X-axis direction and the Y-axis direction (rotated about a Z axis) by the balls 35 to 37. The above-described anti-vibration function is implemented by the stationary member 30 and the movable member 31. The Z axis is parallel to the optical axis OA.

The stationary member 30 holds a magnet 40, a magnet 41, and a magnet 42. The magnets 40 to 42 are mounted on a front surface of the stationary member 30 facing the movable member 31. Each of the magnets 40 to 42 is a set of a sheet-like magnet of which an N pole faces the movable member 31 and a sheet-like magnet of which an S pole faces the movable member 31. The magnet 40 is disposed in the middle of a lower portion of the stationary member 30 such that a long side of the magnet 40 is along the X-axis direction. The magnet 41 and the magnet 42 are arranged in the Y-axis direction. The magnet 41 is disposed at an upper left corner of the stationary member 30 such that a long side of the magnet 41 is along the Y-axis direction. The magnet 42 is disposed at a lower left corner of the stationary member 30 such that a long side of the magnet 42 is parallel to the Y-axis direction.

A plate 45, a plate 46, and a plate 47 are mounted on the front surface of the stationary member 30 in addition to the magnets 40 to 42. The plate 45 is disposed above the magnet 40 at a lower right corner of the stationary member 30. The plate 46 is disposed between the magnets 41 and 42 on the left side of the stationary member 30. The plate 47 is disposed at an upper right corner of the stationary member 30. The plate 45 supports the ball 35 such that the ball 35 can roll, the plate 46 supports the ball 36 such that the ball 36 can roll, and the plate 47 supports the ball 37 such that the ball 37 can roll.

A square restriction opening 50 and a square restriction opening 51, which restrict the movement range of the movable member 31 in an XY plane, are formed in the stationary member 30. The restriction openings 50 and 51 have substantially the same size as viewed in the Z-axis direction. The restriction opening 50 is formed between the magnet 42 and the plate 45 at the lower left corner of the stationary member 30. The restriction opening 51 is formed at the upper right corner of the stationary member 30 to be adjacent to the left side of the plate 47. That is, the restriction openings 50 and 51 are disposed at substantially diagonal positions in the stationary member 30.

A female screw 55, a female screw 56, a female screw 57, and a female screw 58 are provided on the stationary member 30 via spacers. The female screw 55 is provided at the lower right corner of the stationary member 30. The female screw 56 is provided at the upper left corner of the stationary member 30. The female screw 57 is provided at the lower left corner of the stationary member 30. The female screw 58 is provided at the upper right corner of the stationary member 30.

A relatively large rectangular access opening 59 is formed at a central portion of the stationary member 30. The access opening 59 is provided for access to the back surface of the movable member 31 from the back surface of the stationary member 30.

The movable member 31 holds the imaging element 16, and holds a coil 60, a coil 61, and a coil 62. The imaging element 16 is disposed at a central portion of the movable member 31. The coil 60 is disposed at a position facing the magnet 40 in the Z-axis direction in the middle of a lower portion of the movable member 31. The coil 61 is disposed at a position facing the magnet 41 in the Z-axis direction at an upper left corner of the movable member 31. The coil 62 is disposed at a position facing the magnet 42 in the Z-axis direction at a lower left corner of the movable member 31. The coil 60 is disposed such that a long side of the coil 60 is along the X-axis direction. The coils 61 and 62 are arranged in the Y-axis direction. Each of the coils 61 and 62 is disposed such that a long side of each of the coils 61 and 62 is parallel to the Y-axis direction.

A magnet 65 is held by the yoke 32. Further, a magnetic body 66 is mounted on the coil 61, and a magnetic body 67 is mounted on the coil 62. The magnet 65 is, for example, a neodymium magnet. The magnetic bodies 66 and 67 are, for example, thin plate pieces made of iron. The magnet 65 is disposed to cover the coil 60, and increases a drive force of the coil 60. The magnetic bodies 66 and 67 are arranged in the Y-axis direction. The magnetic body 66 is disposed on the upper end side of the coil 61, and the magnetic body 67 is disposed on the lower end side of the coil 62.

Since the coil 60 is disposed at a position facing the magnet 40 in the Z-axis direction as described above, the magnet 65 is also disposed at a position facing the magnet 40 in the Z-axis direction. For this reason, the magnet 65 is attracted to the magnet 40 in a state where the magnet 65 is fixed to the yoke 32.

Likewise, since the coil 61 is disposed at a position facing the magnet 41 in the Z-axis direction as described above, the magnetic body 66 is also disposed at a position facing the magnet 41 in the Z-axis direction. For this reason, the magnetic body 66 is attracted to the magnet 41. Further, since the coil 62 is disposed at a position facing the magnet 42 in the Z-axis direction as described above, the magnetic body 67 is also disposed at a position facing the magnet 42 in the Z-axis direction. For this reason, the magnetic body 67 is attracted to the magnet 42.

A recessed portion 70, a recessed portion 71, and a recessed portion 72 are formed on a rear surface of the movable member 31 facing the stationary member 30. The recessed portion 70 is disposed at a position facing the plate 45 in the Z-axis direction at a lower right corner of the movable member 31. The recessed portion 71 is disposed at a position facing the plate 46 in the Z-axis direction between the coils 61 and 62 provided on the left side of the movable member 31. The recessed portion 72 is disposed at a position facing the plate 47 in the Z-axis direction at an upper right corner of the movable member 31. The recessed portion 70 houses the ball 35 to allow the ball 35 to roll, the recessed portion 71 houses the ball 36 to allow the ball 36 to roll, and the recessed portion 72 houses the ball 37 to allow the ball 37 to roll. The sizes of the recessed portions 70 to 72 in a case of being viewed in the Z-axis direction are slightly larger than the diameters of the balls 35 to 37, respectively. Further, the depths of the recessed portions 70 to 72 in the Z-axis direction are slightly smaller than the diameters of the balls 35 to 37, respectively.

A columnar protrusion 80, which protrudes toward the stationary member 30, is provided on the rear surface of the movable member 31 at a position facing the restriction opening 50 in the Z-axis direction. Further, a columnar protrusion 81, which protrudes toward the stationary member 30, is provided at a position facing the restriction opening 51 in the Z-axis direction on the rear surface of the movable member 31. The protrusion 80 is inserted into the restriction opening 50. Further, the protrusion 81 is inserted into the restriction opening 51. For this reason, the protrusions 80 and 81 act as restriction pins that restrict the movement of the movable member 31 in the XY plane.

The yoke 32 is, for example, a magnetic body, such as a thin plate made of iron, and has a substantially C-shape. The yoke 32 forms a magnetic circuit together with the magnets 40 to 42, and increases magnetic flux that is received by the coils 60 to 62.

A male screw 85, a male screw 86, a male screw 87, and a male screw 88 are mounted on the yoke 32. The male screws 85 to 88 are fastened and fixed to the female screws 55 to 58 of the stationary member 30. Accordingly, the stationary member 30 and the yoke 32 are fixed to each other and the movable member 31 is movably held between the stationary member 30 and the yoke 32.

The imaging element unit 15 comprises a pair of voice coil motors (VCMs). The pair of VCMs is a pair formed of a first VCM and a second VCM. The first VCM comprises a pair formed of the magnet 40 and the coil 60 and the yoke 32, and generates power that is used to move the movable member 31 in the Y-axis direction. On the other hand, the second VCM comprises a pair formed of the magnet 41 and the coil 61, a pair formed of the magnet 42 and the coil 62, and the yoke 32, and generates power that is used to move the movable member 31 in the X-axis direction. More specifically, the first VCM generates power that is used to move the movable member 31 in the Y-axis direction with a magnetic force of the magnet 40 and a current flowing through the coil 60. Further, the second VCM generates power that is used to move the movable member 31 in the X-axis direction with a magnetic force of the magnet 41, a current flowing through the coil 61, a magnetic force of the magnet 42, and a current flowing through the coil 62.

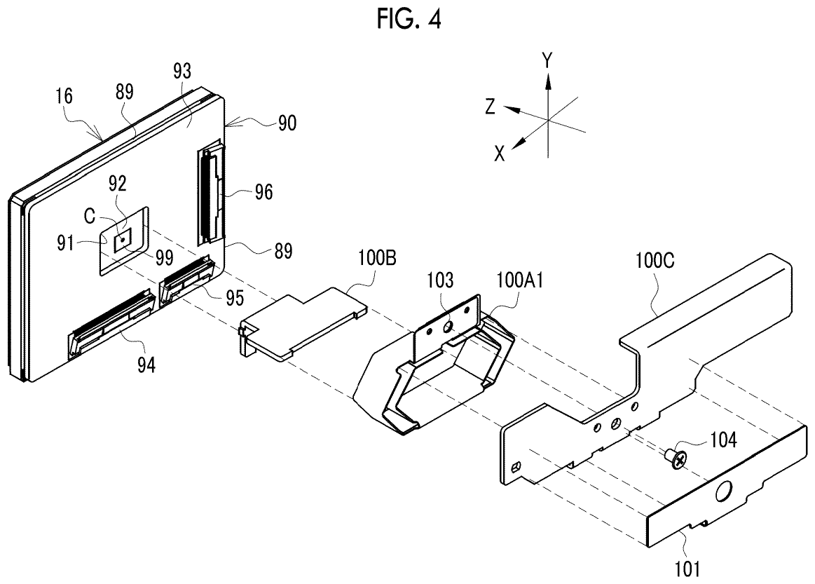

As also shown in FIG. 4, a rectangular circuit board 90 having substantially the same size as the imaging element 16 is mounted on a back surface 89 of the imaging element 16 opposite to the imaging surface 17. The circuit board 90 is made of a resin, such as epoxy. A rectangular opening 91 is formed in the circuit board 90. The opening 91 is formed at a central portion of the circuit board 90, and causes a central region 92 of the back surface 89 of the imaging element 16 to be exposed therethrough. The central region 92 is a region that is centered on a center point C of the back surface 89 of the imaging element 16, surrounds the center point C, and has a preset size. Identification information 99 of the imaging element 16 is written in the central region 92. The opening 91 is formed for the visual recognition of the identification information 99. The identification information 99 is, for example, a two-dimensional barcode that is used to move to an internet page in which a management number and/or management information is written.

Electric circuits, such as a control circuit, a drive circuit, and a power circuit for the imaging element 16, are mounted on the circuit board 90. A connector 94 and a connector 95 are provided at a lower end of a back surface 93 of the circuit board 90. Further, a connector 96 is provided at a left end of the back surface 93 of the circuit board 90.

One end of a flexible board 97 (see FIGS. 2 and 3) is connected to the connector 94 and the connector 95. The other end of the flexible board 97 is led out to a back side of the stationary member 30 through the access opening 59. The other end of the flexible board 97 is connected to the CPU 18, a power feed circuit (not shown) that feeds power from a battery, and the like. Further, one end of a flexible board 98 (see FIG. 1) is connected to the connector 96. The other end of the flexible board 98 wraps around a front surface of the movable member 31 and is connected to the imaging element 16. In summary, the other end of the flexible board 98 is connected to the imaging element 16, and one end of the flexible board 98 is connected to the connector 96. Further, one end of the flexible board 97 is connected to the connectors 94 and 95, and the CPU 18 and the like are connected to the other end of the flexible board 97. For this reason, the imaging element 16, the circuit board 90, the CPU 18, and the like are connected via the flexible board 98, the connectors 96, 94, and 95, and the flexible board 97.

The imaging element unit 15 further includes a thermally conductive member 100A1, a thermally conductive member 100B, and a thermally conductive member 100C to which heat (driving heat) of the imaging element 16 is conducted, and a reinforcing member 101.

The thermally conductive members 100B and 100C are connected to the thermally conductive member 100A1. Heat is conducted to the thermally conductive member 100A1 from the thermally conductive member 100B. Further, the thermally conductive member 100A1 conducts heat to the thermally conductive member 100C. The thermally conductive member 100B is connected to the central region 92 of the back surface 89 of the imaging element 16 that is exposed through the opening 91. Heat is conducted to the thermally conductive member 100B from the central region 92.

The thermally conductive members 100A1 and 100B are fixed to each other by an adhesive. A female screw 68 (see FIG. 3) is formed in the stationary member 30. An insertion hole 103 is formed in the thermally conductive member 100A1. A male screw 104 is mounted on the thermally conductive member 100C. The male screw 104 passes through the insertion hole 103 of the thermally conductive member 100A1, and is fastened and fixed to the female screw 68 of the stationary member 30. Accordingly, the thermally conductive members 100A1 and 100C are fixed to each other.

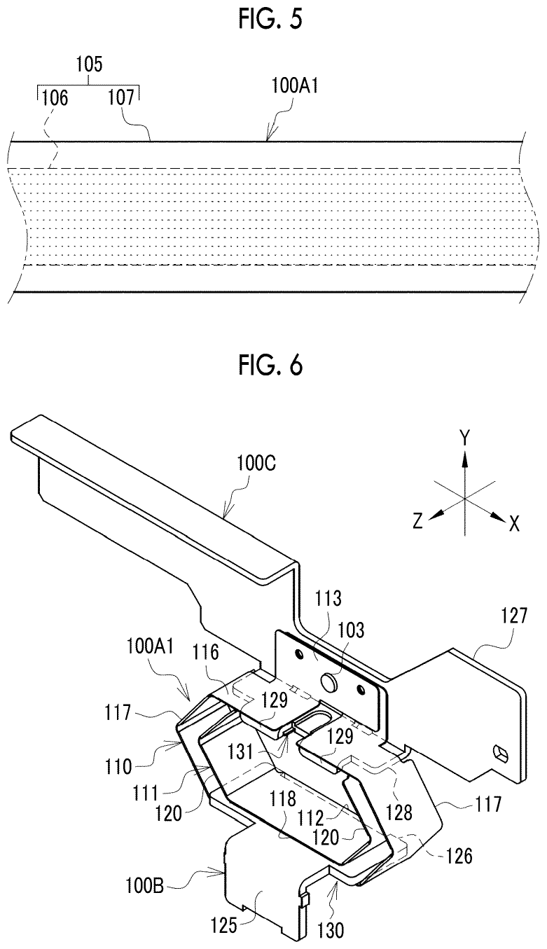

For example, as shown in FIG. 5, the thermally conductive member 100A1 is formed of a graphite sheet 105. For this reason, the thermally conductive member 100A1 can be caused to have appropriate elasticity. The graphite sheet 105 has a configuration in which graphite 106 is pouched with a resin film 107, such as a polyethylene terephthalate (PET) film, wider than the graphite 106. A thickness of the graphite 106 is, for example, 70 μm, and a thickness of the resin film 107 is, for example, 5 μm. The graphite sheet 105 is an example of a “thermally conductive layer” according to the technique of the present disclosure. The graphite 106 is an example of a “thermally conductive material” according to the technique of the present disclosure. The resin film 107 is an example of a “coating material” according to the technique of the present disclosure.

Each of the thermally conductive members 100B and 100C is a metal plate, for example, a copper plate. For this reason, the thermally conductive members 100B and 100C have higher stiffness than the thermally conductive member 100A1 formed of the graphite sheet 105. In other words, the thermally conductive member 100A1 has higher elasticity than the thermally conductive members 100B and 100C.

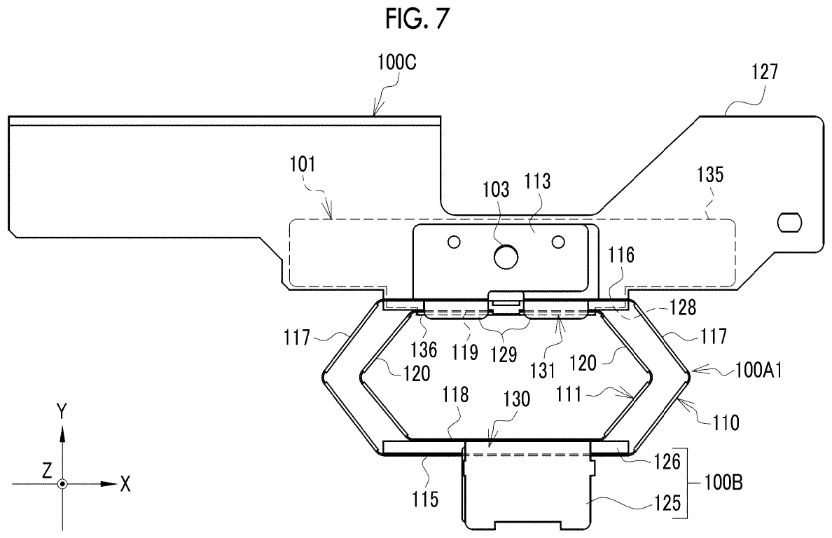

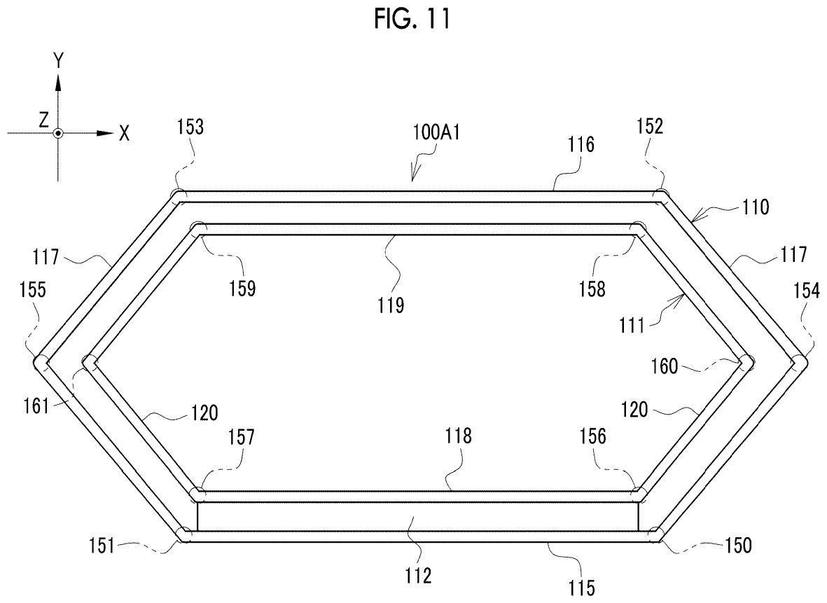

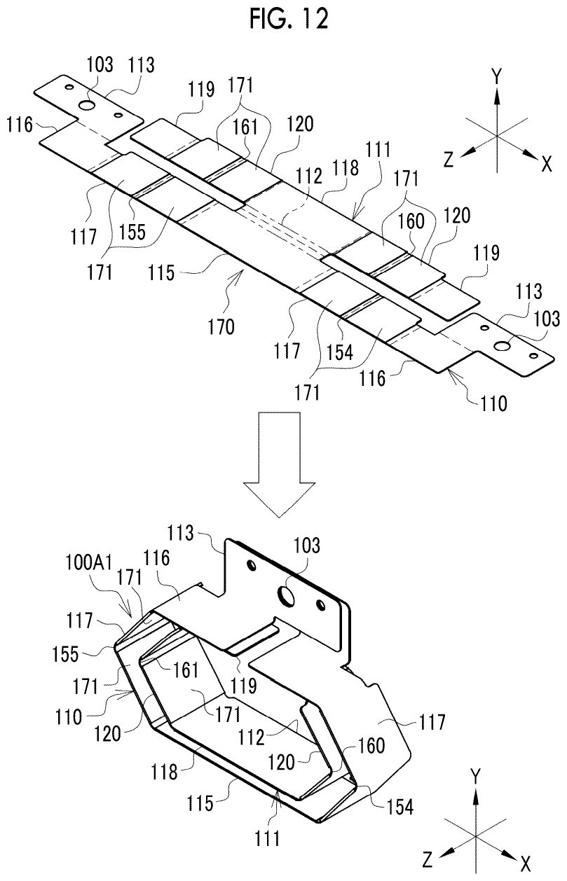

For example, as shown in FIGS. 6 and 7, the first thermally conductive member 100A1 has a double-layer structure that includes an outer layer portion 110 and an inner layer portion 111. The inner layer portion 111 is connected to the outer layer portion 110 via a connecting portion 112 (see also FIGS. 11 and 12), and is disposed inside the outer layer portion 110. More specifically, the inner layer portion 111 is disposed in a space surrounded by the outer layer portion 110. A mounting portion 113 in which the insertion hole 103 is formed is provided at an upper portion of the outer layer portion 110.

Both the outer layer portion 110 and the inner layer portion 111 have a hexagonal shape as viewed in the Z-axis direction. The outer layer portion 110 includes a first sheet portion 115, a second sheet portion 116 that has the same length as the first sheet portion 115 and faces the first sheet portion 115, and a pair of V-shaped connecting portions 117 that connects the first sheet portion 115 and the second sheet portion 116. Similarly, the inner layer portion 111 includes a first sheet portion 118, a second sheet portion 119 that has the same length as the first sheet portion 118 and faces the first sheet portion 118, and a pair of V-shaped connecting portions 120 that connects the first sheet portion 118 and the second sheet portion 119. The first and second sheet portions 115 and 116 and the first and second sheet portions 118 and 119 have a planar shape.

The thermally conductive member 100B includes a first piece 125 and a second piece 126. The first piece 125 is parallel to the imaging surface 17 and the back surface 89 of the imaging element 16, and faces the back surface 89 of the imaging element 16. The first piece 125 is connected to the central region 92 of the back surface 89. The second piece 126 is bent from the first piece 125 at an angle of 90°, and extends in a normal direction of the imaging surface 17 and the back surface 89 of the imaging element 16. The normal direction of the imaging surface 17 and the back surface 89 of the imaging element 16 is the Z-axis direction (a direction of the optical axis OA). The second piece 126 has substantially the same size as a space between the first sheet portion 115 of the outer layer portion 110 and the first sheet portion 118 of the inner layer portion 111.

At a member connecting portion 130 where the thermally conductive members 100A1 and 100B are connected to each other, the thermally conductive member 100B is connected to the thermally conductive member 100A1 through the second piece 126. More specifically, the second piece 126 is inserted into the space between the first sheet portion 115 of the outer layer portion 110 and the first sheet portion 118 of the inner layer portion 111, and is held in a state where the second piece 126 is interposed between the first sheet portions 115 and 118. A double-sided adhesive tape is attached to each of portions of the first sheet portions 115 and 118 that are in contact with the second piece 126. The first sheet portion 115, the first sheet portion 118, the second piece 126 and, by extension, the thermally conductive members 100A1 and 100B are fixed to each other by an adhesive of the double-sided adhesive tape. The member connecting portion 130 is a portion at which the second piece 126 of the thermally conductive member 100B is inserted into a space between the first sheet portion 115 of the outer layer portion 110 of the thermally conductive member 100A1 and the first sheet portion 118 of the inner layer portion 111 and is held in a state of being interposed between the first sheet portions 115 and 118.

The thermally conductive member 100C includes a first piece 127 and a second piece 128. The first piece 127 is parallel to the imaging surface 17 and the back surface 89 of the imaging element 16 as with the first piece 125 of the thermally conductive member 100B, and has the shape of a wing long in the X-axis direction. As with the second piece 126 of the thermally conductive member 100B, the second piece 128 is bent from the first piece 127 at an angle of 90° and extends in the normal direction of the imaging surface 17 and the back surface 89 of the imaging element 16.

The thermally conductive members 100A1 and 100C are connected to each other at a member connecting portion 131. The member connecting portion 131 is a portion at which the second piece 128 of the thermally conductive member 100C is inserted into a space between the second sheet portion 116 of the outer layer portion 110 of the thermally conductive member 100A1 and the second sheet portion 119 of the inner layer portion 111 and is held in a state of being interposed between the second sheet portion 116 and the second sheet portion 119. The second piece 128 is provided with claws 129 that are caught by an edge of the second sheet portion 119. The claws 129 position the second sheet portion 119.

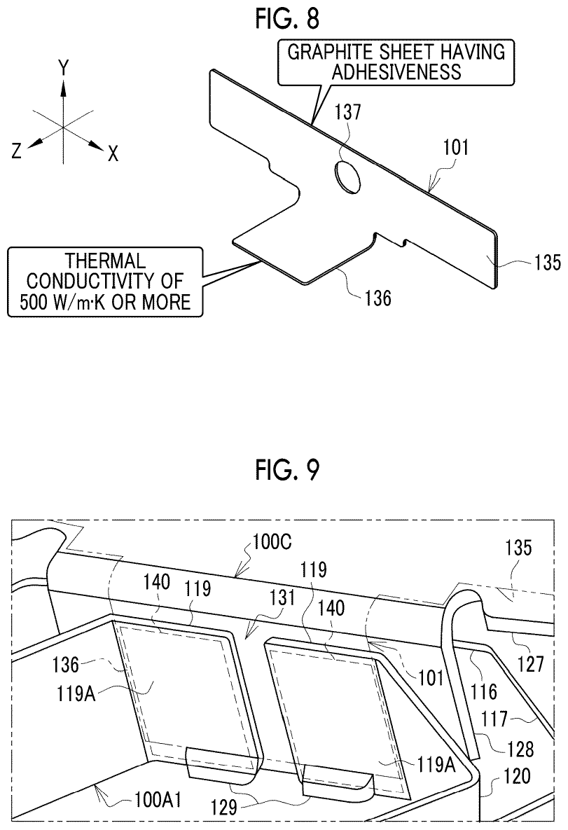

For example, as shown in FIG. 8, the reinforcing member 101 includes a first piece 135 and a second piece 136. The first piece 135 is parallel to the imaging surface 17 and the back surface 89 of the imaging element 16 as with the first piece 127 of the thermally conductive member 100C, and has the shape of a wing long in the X-axis direction. An insertion hole 137 into which the male screw 104 is to be inserted is formed in the first piece 135. As with the second piece 128 of the thermally conductive member 100C, the second piece 136 is bent from the first piece 135 at an angle of 90° and extends in the normal direction of the imaging surface 17 and the back surface 89 of the imaging element 16.

The reinforcing member 101 is formed of a graphite sheet 105, similar to the thermally conductive member 100A1. For this reason, the reinforcing member 101 can be caused to have appropriate elasticity. The thermally conductive material included in the reinforcing member 101, here, the graphite 106 has a thermal conductivity of 500 W/m·K or more, and more preferably 1000 W/m. K or more. Further, the thermally conductive material included in the reinforcing member 101, here, the graphite 106 has a thermal conductivity of 5000 W/m·K or less. The thermal conductivity can be measured using a ThermoWave Analyzer TA manufactured by Bethel Co., Ltd.

Furthermore, the reinforcing member 101 has adhesiveness. More specifically, the reinforcing member 101 is a single-sided pressure-sensitive adhesive seal in which an adhesive layer is provided on a surface seen in FIG. 8 and facing the second sheet portion 119 of the thermally conductive member 100A1 and the first piece 127 of the thermally conductive member 100C.

For example, as shown in FIG. 9, at the member connecting portion 131, a double-sided adhesive tape 140 is attached to the second sheet portion 119 of the inner layer portion 111 of the thermally conductive member 100A1 and the second piece 128 of the thermally conductive member 100C. More specifically, the second sheet portion 119 is divided into two portions in a middle portion thereof, and the double-sided adhesive tape 140 is attached to each of the two divided portions of the second sheet portion 119. The second sheet portion 119 and the second piece 128 and, by extension, the thermally conductive members 100A1 and 100C are fixed to each other by an adhesive of the double-sided adhesive tape 140. The reinforcing member 101 is provided only at the member connecting portion 131, but the present disclosure is not limited thereto. The reinforcing member 101 may be provided at the member connecting portion 130 instead of or in addition to the member connecting portion 131.

The first piece 135 of the reinforcing member 101 is adhered to the first piece 127 of the thermally conductive member 100C (see also FIG. 7). Further, the second piece 136 of the reinforcing member 101 is adhered to a surface 119A of the second sheet portion 119 of the thermally conductive member 100A1 (see also FIG. 7). The first piece 135 has a size large enough to cover up a lower half of the first piece 127 of the thermally conductive member 100C. Furthermore, the second piece 136 has a size large enough to cover up the entire second sheet portion 119. The surface 119A of the second sheet portion 119 to which the second piece 136 is adhered is a surface opposite to a bonding surface between the thermally conductive members 100A1 and 100C that are adhered to each other by the double-sided adhesive tape 140. In this way, the first piece 135 and the second piece 136 are adhered to the first piece 127 and the second sheet portion 119, respectively, so that the reinforcing member 101 reinforces connection between the thermally conductive members 100A1 and 100C at the member connecting portion 131.

A thickness of the thermally conductive member 100B is larger than a thickness of the thermally conductive member 100A1. The thickness of the thermally conductive member 100A1 is, for example, 80 μm, and the thickness of the thermally conductive member 100B is, for example, 1 mm. A thickness of the thermally conductive member 100C is also larger than the thickness of the thermally conductive member 100A1, and is, for example, 1 mm.

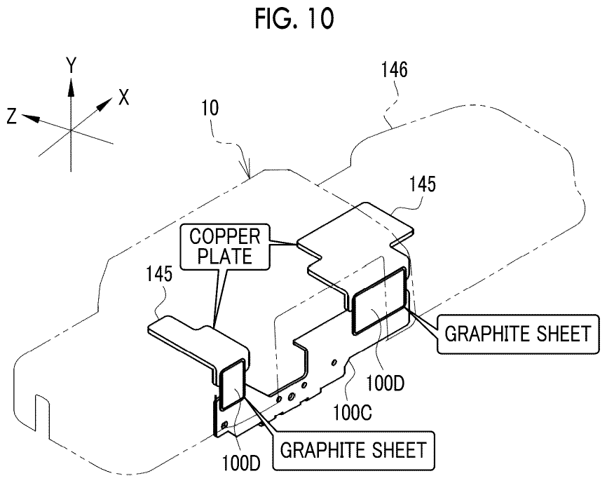

For example, as shown in FIG. 10, thermally conductive members 100D are mounted on the thermally conductive member 100C by an adhesive. The thermally conductive member 100D is formed of a graphite sheet 105 as with the thermally conductive member 100A1 and the like. For this reason, the thermally conductive member 100D can be caused to have appropriate elasticity. A thickness of the thermally conductive member 100D is larger than the thickness of the thermally conductive member 100A1. The thickness of the thermally conductive member 100D is, for example, 500 μm.

A connecting member 145 is further mounted on each of the thermally conductive members 100D by an adhesive. The connecting member 145 is a metal plate, for example, a copper plate as with the thermally conductive members 100B and 100C. The connecting members 145 are connected to a top plate 146 of the camera body 10. The top plate 146 of the camera body 10 is, for example, a magnesium plate or an aluminum plate.

For example, as shown in FIG. 11, the outer layer portion 110 of the thermally conductive member 100A1 has six corners 150, 151, 152, 153, 154, and 155 since having a hexagonal shape as viewed in the Z-axis direction as described above. Since the inner layer portion 111 also has a hexagonal shape as viewed in the Z-axis direction, the inner layer portion 111 has six corners 156, 157, 158, 159, 160, and 161. The corners 150 to 155 and the corners 156 to 161 function as bent portions that allow the first thermally conductive member 100A1 to be deformable to follow the movement of the imaging element 16 caused by the anti-vibration function. Hereinafter, the corners 150 to 161 will be referred to as bent portions 150 to 161.

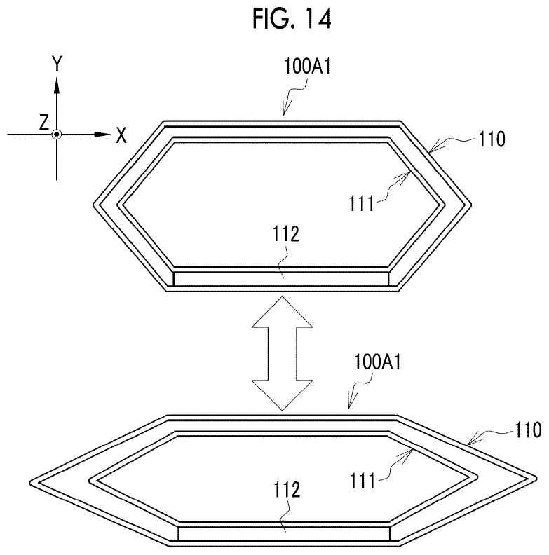

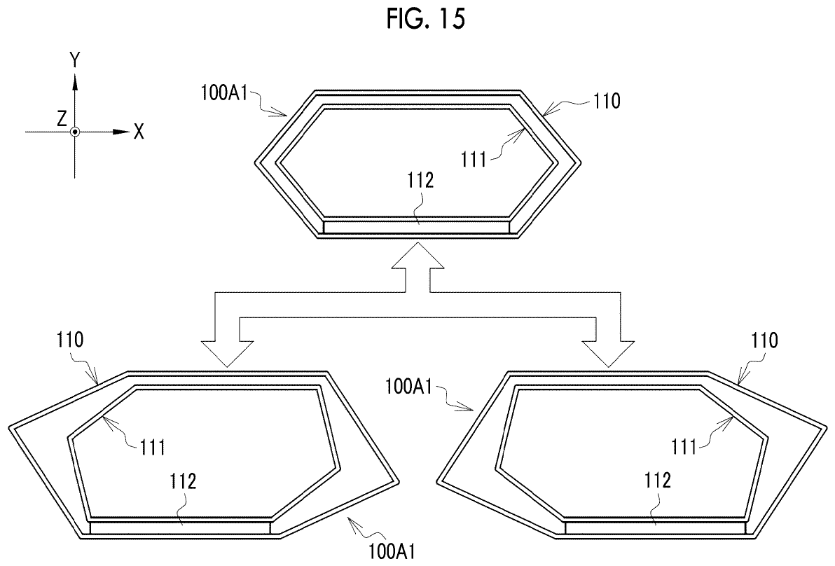

The bent portions 150 to 155 of the outer layer portion 110 protrude outward. Similarly, the bent portions 156 to 161 of the inner layer portion 111 also protrude outward. That is, the thermally conductive member 100A1 has a shape of a pantograph. The mounting portion 113 is not shown in FIG. 11 so that the first thermally conductive member 100A1 is simplified. The same applies to FIGS. 14, 15, and the like.

For example, broken line portions of one sheet-like material 170 are bent, so that the thermally conductive member 100A1 is formed as shown in FIG. 12. Specifically, first, a portion corresponding to the connecting portion 112 is bent by an angle of 180°, so that a portion serving as the outer layer portion 110 and a portion serving as the inner layer portion 111 are caused to face each other. Then, after portions corresponding to the bent portions 156 to 161 are bent to form the inner layer portion 111, portions corresponding to the bent portions 150 to 155 are bent to form the outer layer portion 110. Finally, a portion serving as the mounting portion 113 is bent, so that the thermally conductive member 100A1 is completed.

The thermally conductive member 100A1 includes reinforcing graphite sheets 171. The reinforcing graphite sheet 171 is formed of graphite and a resin film as with the graphite sheet 105. The reinforcing graphite sheets 171 are provided on two sides that form each of the connecting portions 117 and 120, and are not provided on the bent portions 154, 155, 160, and 161. That is, the two sides forming each of the connecting portions 117 and 120 have a configuration in which the graphite sheet 105 and the reinforcing graphite sheet 171 are laminated. On the other hand, each of the bent portions 154, 155, 160, and 161 is formed of only one graphite sheet 105. Accordingly, the number of graphite sheets laminated in each of the two sides forming each of the connecting portions 117 and 120 is larger than that in each of the bent portions 154, 155, 160, and 161.

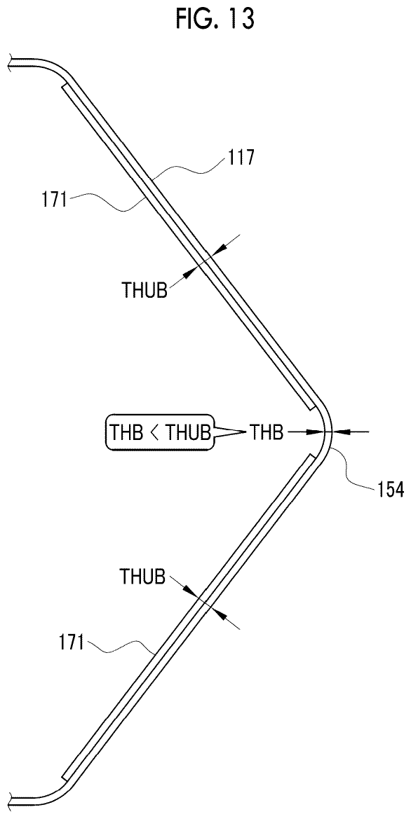

For this reason, for example, as shown in FIG. 13, a thicknesses THUB of each of the two sides forming each of the connecting portions 117 and 120 is larger than a thicknesses THB of each of the bent portions 154, 155, 160, and 161 by the thicknesses of the reinforcing graphite sheet 171 (THB<THUB). In other words, each of the bent portions 154, 155, 160, and 161 is thinner than each of the two sides forming each of the connecting portions 117 and 120 other than the bent portions. The reinforcing graphite sheet 171 and the graphite sheet 105 of each of the connecting portions 117 and 120 are an example of a “thermally conductive layer” according to the technique of the present disclosure. Further, the two sides forming each of the connecting portions 117 and 120 are an example of an “unbent portion” according to the technique of the present disclosure. In FIG. 13, the connecting portion 117 and the bent portion 154 are shown as representatives.

For example, as shown in FIGS. 14 and 15, the thermally conductive member 100A1 is deformed to be capable of following the movement of the imaging element 16 caused by the anti-vibration function. FIG. 14 shows an aspect in which the thermally conductive member 100A1 is flexibly deformed in a vertical direction to follow the movement of the imaging element 16 in the Y-axis direction caused by the anti-vibration function. FIG. 15 shows an aspect in which the thermally conductive member 100A1 is obliquely deformed in a horizontal direction to follow the movement of the imaging element 16 in the X-axis direction caused by the anti-vibration function. The Y-axis direction is an example of a “direction in which the thermally conductive member expands and contracts” according to the technique of the present disclosure.

Next, an action of the above-described configuration will be described. In the digital camera 2, heat that cannot be ignored is generated in the imaging element 16 in a case where imaging in which a relatively large load is applied to the imaging element 16 is performed, such as a case where a video with 120 frames per second is captured with an image quality equivalent to a resolution of 4K (4K/120 p).

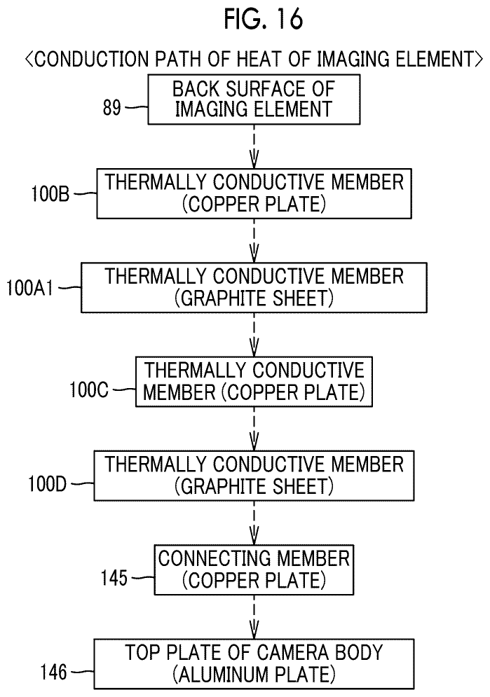

In the imaging element unit 15 according to the present embodiment, the heat of the imaging element 16 follows a conduction path shown in FIG. 16 as an example. That is, the heat of the imaging element 16 is conducted from the back surface 89 of the imaging element 16 to the thermally conductive member 100B connected to the central region 92 of the back surface 89 first. Next, the heat is conducted from the thermally conductive member 100B to the thermally conductive member 100A1 connected through the second piece 126 of the thermally conductive member 100B.

The heat conducted to the thermally conductive member 100A1 is conducted to the thermally conductive member 100C connected through the second piece 128. Furthermore, the heat is conducted to the thermally conductive members 100D from the thermally conductive member 100C and is conducted to the connecting members 145 from the thermally conductive members 100D. Then, the heat is conducted to the top plate 146 of the camera body 10 via the connecting members 145, and is dissipated to the outside via the top plate 146.

The imaging element unit 15 is adapted such that the movable member 31 is movable relative to the stationary member 30 and the yoke 32. The movable member 31 holds the imaging element 16. For this reason, as the movable member 31 is moved, the imaging element 16 is also moved. In a case where the misregistration of subject light incident on the imaging surface 17 occurs due to a camera shake caused by a user or the like, the movable member 31 and, by extension, the imaging element 16 are moved under the control of the CPU 18 in a direction in which the misregistration is canceled by a distance that is required to cancel the misregistration. As shown in FIGS. 14 and 15, the thermally conductive member 100A1 is deformed to follow the movement of the imaging element 16 caused by the anti-vibration function.

As described above, the imaging element unit 15 comprises the imaging element 16 that images a subject, the thermally conductive members 100A1 and 100C to which heat of the imaging element 16 is conducted and which are connected to each other at the member connecting portion 131, and the reinforcing member 101. The reinforcing member 101 reinforces the connection between the thermally conductive members 100A1 and 100C at the member connecting portion 131. Therefore, it is possible to make it difficult for the thermally conductive members 100A1 and 100C to be disconnected from each other. As described above, the reinforcing member 101 may be provided at the member connecting portion 130 and connection between the thermally conductive members 100A1 and 100B may be reinforced by the reinforcing member 101.

The thermally conductive members 100A1 and 100C are adhered to each other by the double-sided adhesive tape 140 attached to the second sheet portion 119 of the inner layer portion 111 of the thermally conductive member 100A1 and the second piece 128 of the thermally conductive member 100C. However, in a case where an adhesive force of the double-sided adhesive tape 140 is increased, thermal conductivity from the thermally conductive member 100A1 to the thermally conductive member 100C deteriorates as that much. Accordingly, it is not possible to increase the adhesive force of the double-sided adhesive tape 140 so much. For this reason, there is a concern that the thermally conductive members 100A1 and 100C may be disconnected from each other in a case where only the adhesive force of the double-sided adhesive tape 140 is used. Therefore, the connection between the thermally conductive members 100A1 and 100C is reinforced by the reinforcing member 101, which makes it difficult for the thermally conductive members 100A1 and 100C to be disconnected from each other.

A reinforcing member that reinforces connection between the first sheet portions 115 and 118 of the thermally conductive member 100A1 and the second piece 126 of the thermally conductive member 100B may be provided. However, the second sheet portion 119 is divided into two portions. For this reason, connection between the second sheet portion 119 and the second piece 128 of the thermally conductive member 100C is weaker than the connection between the first sheet portions 115 and 118, which are not divided, and the second piece 126 of the thermally conductive member 100B. Therefore, there is a high necessity to reinforce the connection between the thermally conductive members 100A1 and 100C by the reinforcing member 101 as in the present example.

The imaging element unit 15 has an anti-vibration function to move the imaging element 16 in the plane directions of the imaging surface 17. As shown in FIGS. 14 and 15, the thermally conductive member 100A1 is deformed to be capable of following the movement of the imaging element 16 caused by the anti-vibration function. Due to the deformation of the thermally conductive member 100A1, the thermally conductive members 100A1 and 100C are more likely to be disconnected from each other. Therefore, an effect that can make it difficult for the thermally conductive members 100A1 and 100C to be disconnected from each other can be further exhibited.

The reinforcing member 101 is adhered to the thermally conductive members 100A1 and 100C by an adhesive at the member connecting portion 131. The connection between the thermally conductive members 100A1 and 100C can be reinforced more firmly by the reinforcing member 101.

The reinforcing member 101 includes the thermally conductive material having a thermal conductivity of 500 W/m·K or more. For this reason, the reinforcing member 101 can play not only a role to reinforce the connection between the thermally conductive members 100A1 and 100C but also a role to conduct heat of the imaging element 16.

The inner layer portion 111 is disposed in a space formed by the outer layer portion 110. For this reason, the space formed by the outer layer portion 110 can be effectively utilized as a place in which the inner layer portion 111 is disposed.

As shown in FIGS. 12 and 13, the structure of each of the bent portions 154, 155, 160, and 161 is different from the structure of each of the two sides forming each of the connecting portions 117 and 120 that are the unbent portions. Specifically, each of the bent portions 154, 155, 160, and 161 includes one graphite sheet 105 including the graphite 106. Further, the number of graphite sheets laminated in each of the two sides forming each of the connecting portions 117 and 120, which are the unbent portions, is larger than that in each of the bent portions 154, 155, 160, and 161, due to the reinforcing graphite sheet 171. Furthermore, the bent portions 154, 155, 160, and 161 are thinner than the two sides forming each of the connecting portions 117 and 120 that are unbent portions. For this reason, the thermally conductive member 100A1 can be caused to have an appropriate structure. Specifically, the resistance of the bent portions 154, 155, 160, and 161 during bending can be reduced. The thermally conductive member 100A1 can be smoothly deformed to follow the movement of the imaging element 16 caused by the anti-vibration function. That is, a movable load of the thermally conductive member 100A1 can be reduced. In addition, unintended deformation of the two sides forming each of the connecting portions 117 and 120 can be prevented by the reinforcing graphite sheets 171. The reinforcing graphite sheets 171 may be provided on the first sheet portions 115 and 118 and the second sheet portions 116 and 119 in addition to the two sides forming each of the connecting portions 117 and 120.

In the two sides forming each of the connecting portions 117 and 120, a plurality of pieces of the graphite 106 may be laminated and may then be collectively pouched with the resin film 107. As a result, the two sides forming each of the connecting portions 117 and 120 may be made to be thicker than the bent portions 154, 155, 160, and 161. In this case, the graphite 106 is an example of a “thermally conductive layer” according to the technique of the present disclosure.

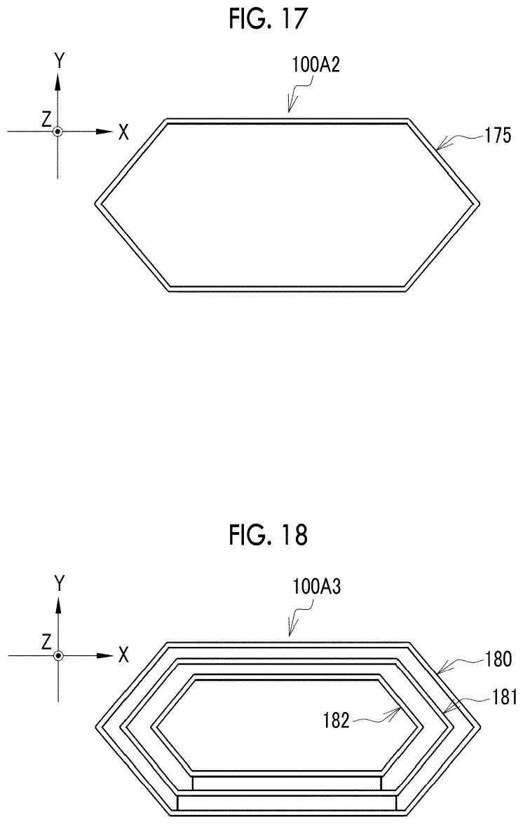

Although the thermally conductive member 100A1 having a double-layer structure including the outer layer portion 110 and the inner layer portion 111 has been exemplified, the present disclosure is not limited thereto. For example, a thermally conductive member 100A2 including only one outer layer portion 175 may be provided as shown in FIG. 17. Further, the number of inner layer portions 111 is not limited to one. For example, a triple-layer structure including one outer layer portion 180 and two inner layer portions 181 and 182 disposed inside the outer layer portion 180 (in a space surrounded by the outer layer portion 180) may be provided as in a thermally conductive member 100A3 shown in FIG. 18.

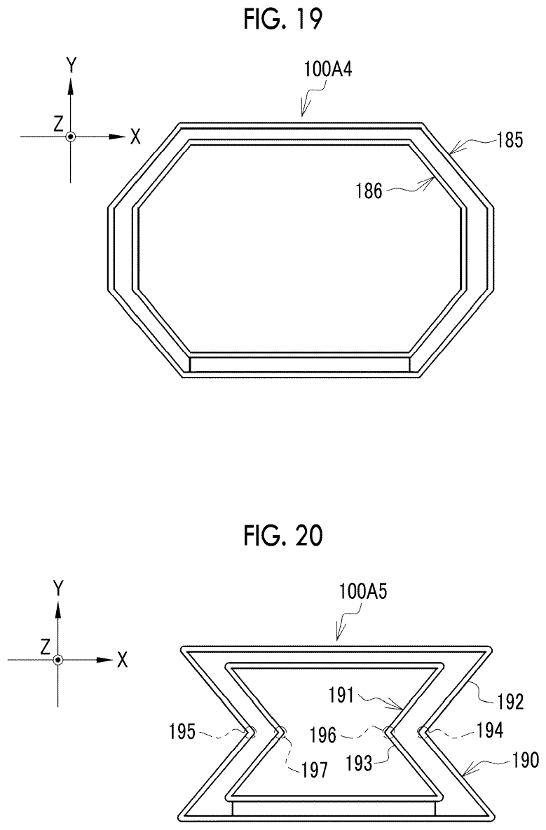

Further, the shape of the thermally conductive member as viewed in the Z-axis direction is not limited to a hexagonal shape. For example, as in a thermally conductive member 100A4 shown in FIG. 19, an outer layer portion 185 and an inner layer portion 186 may have an octagonal shape as viewed in the Z-axis direction. Furthermore, for example, as shown in FIG. 20, a thermally conductive member 100A5 in which corners 194 and 195 of connecting portions 192 of an outer layer portion 190 and corners 196 and 197 of connecting portions 193 of an inner layer portion 191 are recessed inward may be provided. The corners 194 to 197 function as bent portions. The thermally conductive member 100A5 has, so to speak, a shape in which “E” and a mirror image thereof are combined with each other. However, it is preferable that the bent portions 154, 155, 160, and 161 protrude outward as in the thermally conductive member 100A1 of the first embodiment, since a large space surrounded by the outer layer portion 110 can be obtained and the inner layer portion 111 can be easily formed.

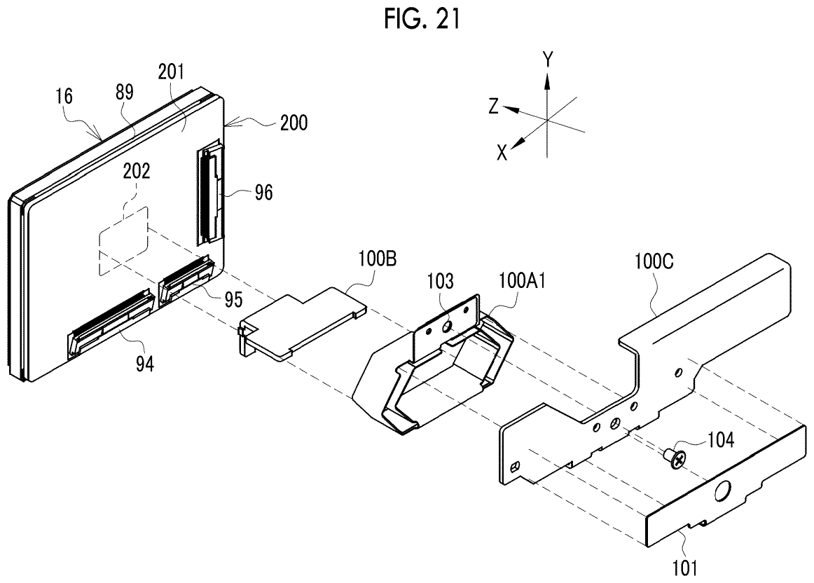

An example in which the opening 91 through which the central region 92 of the back surface 89 of the imaging element 16 is exposed is formed in the circuit board 90 and the first piece 125 of the thermally conductive member 100B is connected to the central region 92 via the opening 91 has been described in the first embodiment, but the present disclosure is not limited thereto. For example, as shown in FIG. 21, the thermally conductive member 100B may be connected to a central region 202 of a back surface 201 of a circuit board 200 not including the opening 91.

Further, although not shown, the circuit board not including the opening 91 and the thermally conductive member 100B may be connected to each other via thermally conductive gel or the like.

### Second Embodiment

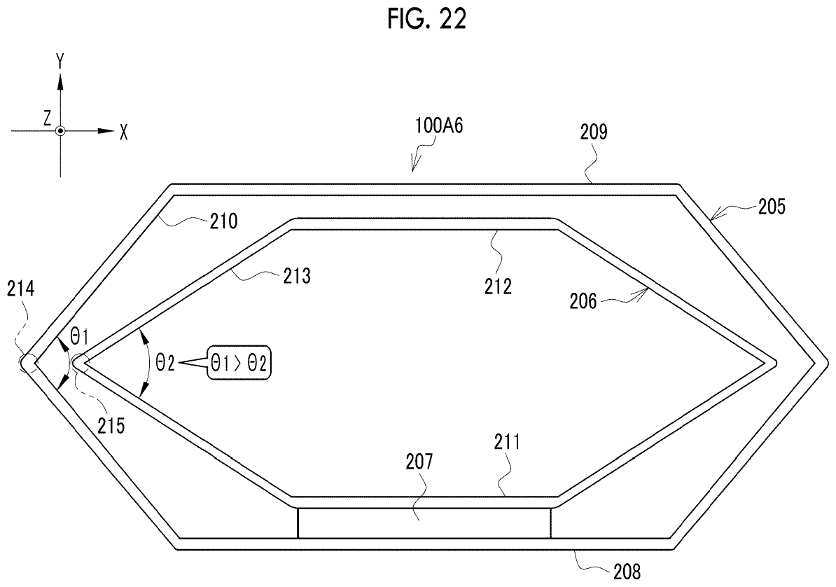

For example, as shown in FIG. 22, a thermally conductive member 100A6 of a second embodiment includes an outer layer portion 205 and an inner layer portion 206 disposed inside the outer layer portion 205 (in a space surrounded by the outer layer portion 205). Both the outer layer portion 205 and the inner layer portion 206 have a hexagonal shape as viewed in the Z-axis direction. The outer layer portion 205 and the inner layer portion 206 are connected to each other via a connecting portion 207. The outer layer portion 205 includes a first sheet portion 208, a second sheet portion 209 that has the same length as the first sheet portion 208 and faces the first sheet portion 208, and a pair of V-shaped connecting portions 210 that connects the first sheet portion 208 and the second sheet portion 209. Similarly, the inner layer portion 206 includes a first sheet portion 211, a second sheet portion 212 that has the same length as the first sheet portion 211 and faces the first sheet portion 211, and a pair of V-shaped connecting portions 213 that connects the first sheet portion 211 and the second sheet portion 212.

Each connecting portion 210 includes a bent portion 214, and each connecting portion 213 includes a bent portion 215. The bent portion 214 is a corner between two sides forming the connecting portion 210, and the bent portion 215 is a corner between two sides forming the connecting portion 213. Both the bent portions 214 and 215 protrude outward. In a case where the anti-vibration function is not working and the imaging element 16 is present at a home position, a bending angle θ1 of the bent portion 214 is larger than a bending angle θ2 of the bent portion 215 (θ1>θ2).

For this reason, the inner layer portion 206 can obtain a large amount of expansion or contraction in the vertical direction with a small change in the bent portion 215, as compared to a case where the bending angle θ2 is equal to or larger than the bending angle θ1. As a result, a movable load of the thermally conductive member 100A6 can be reduced. Further, since the bent portions 214 and 215 protrude outward, a large space surrounded by the outer layer portion 205 can be obtained and the bending angle θ2 of the bent portion 215 can be made smaller. As in the thermally conductive member 100A5 shown in FIG. 20, the bent portions 214 and 215 may be recessed inward. However, since the bending angle θ2 of the bent portion 215 cannot be made too small in this case, it is preferable that the bent portions 214 and 215 protrude outward.

### Third Embodiment

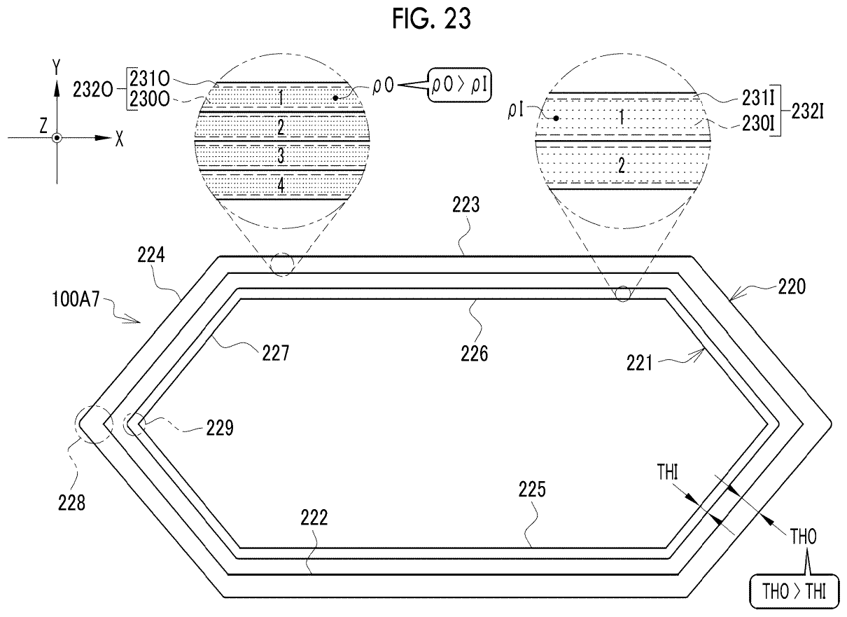

For example, as shown in FIG. 23, a thermally conductive member 100A7 of a third embodiment includes an outer layer portion 220 and an inner layer portion 221 disposed inside the outer layer portion 220 (in a space surrounded by the outer layer portion 220). Both the outer layer portion 220 and the inner layer portion 221 have a hexagonal shape as viewed in the Z-axis direction. The outer layer portion 220 and the inner layer portion 221 are not formed of one sheet-like material 170 unlike in the thermally conductive member 100A1 of the above-described first embodiment or the like, but are formed separately. For this reason, the outer layer portion 220 and the inner layer portion 221 are not connected to each other via a connecting portion unlike in the thermally conductive member 100A1 of the first embodiment or the like.

The outer layer portion 220 includes a first sheet portion 222, a second sheet portion 223 that has the same length as the first sheet portion 222 and faces the first sheet portion 222, and a pair of V-shaped connecting portions 224 that connects the first sheet portion 222 and the second sheet portion 223. Similarly, the inner layer portion 221 includes a first sheet portion 225, a second sheet portion 226 that has the same length as the first sheet portion 225 and faces the first sheet portion 225, and a pair of V-shaped connecting portions 227 that connects the first sheet portion 225 and the second sheet portion 226.

Each connecting portion 224 includes a bent portion 228, and each connecting portion 227 includes a bent portion 229. The bent portion 228 is a corner between two sides forming the connecting portion 224, and the bent portion 229 is a corner between two sides forming the connecting portion 227. Both the bent portions 228 and 229 protrude outward.

A thickness THO of the outer layer portion 220 is larger than a thickness THI of the inner layer portion 221 (THO>THI). Four graphite sheets 232O each of which is formed of graphite 230O and a resin film 231O are laminated, so that the outer layer portion 220 is formed. On the other hand, two graphite sheets 232I each of which is formed of graphite 230I and a resin film 231I are laminated, so that the inner layer portion 221 is formed.

The graphite 230O is thinner than the graphite 230I. Generally, the density of graphite increases as the thickness thereof decreases. For this reason, the density ρO of the graphite 230O is higher than the density ρI of the graphite 230I (ρO>ρI). For example, the thickness and weight of a fragment, which has a size of 50 cm×50 cm, of each of the graphite 230O and the graphite 230I are measured and the weight is divided by the volume of the fragment, so that the densities ρO and ρI are obtained. For this reason, the units of the densities ρO and ρI are g/cm³. The graphite 230O and the graphite 230I are an example of a “thermally conductive material” according to the technique of the present disclosure. The resin films 231O and 231I are example of a “coating material” according to the technique of the present disclosure. Further, the graphite sheets 232O and 232I are examples of a “thermally conductive layer” according to the technique of the present disclosure. In the following description, the graphite sheets 232O and 232I may be collectively referred to as a graphite sheet 232.

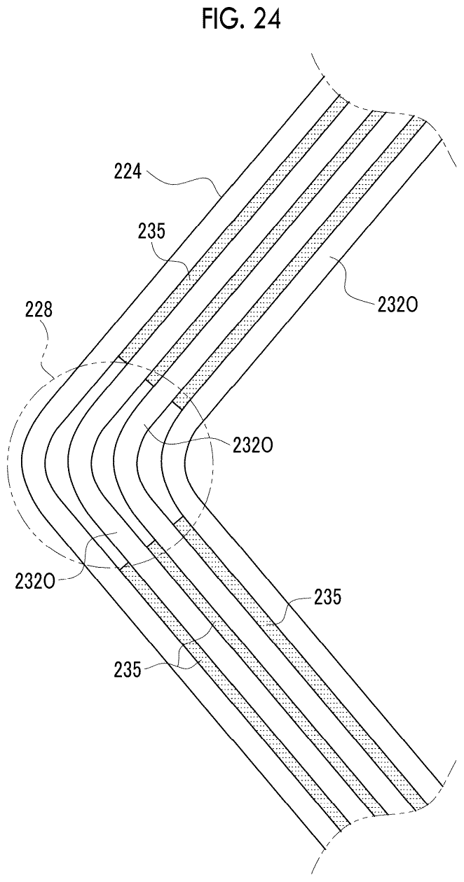

For example, as shown in FIG. 24, the four graphite sheets 232O forming the outer layer portion 220 are not adhered to each other at each bent portion 228 and are adhered to each other by double-sided adhesive tapes 235 at two sides forming each of the connecting portions 224. The two sides forming each of the connecting portions 224 are an example of an “unbent portion” according to the technique of the present disclosure. Although not shown, the two graphite sheets 232I forming the inner layer portion 221 are also not adhered to each other at each bent portion 229 and are adhered to each other at the two sides forming each of the connecting portions 227.

As described above, in the third embodiment, the outer layer portion 220 has a structure of which thermal conductivity is higher than that of the inner layer portion 221, and the inner layer portion 221 has a structure of which mobility is higher than that of the outer layer portion 220. For this reason, the thermal conductivity and the mobility of the thermally conductive member 100A7 can be maintained in balance.

The outer layer portion 220 is thicker than the inner layer portion 221. For this reason, the heat conduction efficiency of the outer layer portion 220 can be easily increased as compared to the heat conduction efficiency of the inner layer portion 221. Further, the resistance of the bent portion 229 of the inner layer portion 221 during bending can be easily reduced as compared to the resistance of the bent portion 228 of the outer layer portion 220 during bending.

A plurality of graphite sheets 232O including graphite 230O are laminated in the outer layer portion 220. Further, the inner layer portion 221 includes the graphite sheets 232I including the graphite 230I. Furthermore, the number of the graphite sheets 232O forming the outer layer portion 220 is four, the number of the graphite sheets 232I forming the inner layer portion 221 is two, and the number of sheets laminated in the outer layer portion 220 is larger than that in the inner layer portion 221. For this reason, the heat conduction efficiency of the outer layer portion 220 can be easily increased as compared to the heat conduction efficiency of the inner layer portion 221. Further, the resistance of the bent portion 229 of the inner layer portion 221 during bending can be easily reduced as compared to the resistance of the bent portion 228 of the outer layer portion 220 during bending.

The graphite 230O included in the graphite sheet 232O forming the outer layer portion 220 has a higher density than the graphite 230I included in the graphite sheet 232I forming the inner layer portion 221. For this reason, the heat conduction efficiency of the outer layer portion 220 can be easily increased as compared to the heat conduction efficiency of the inner layer portion 221. Further, the resistance of the bent portion 229 of the inner layer portion 221 during bending can be easily reduced as compared to the resistance of the bent portion 228 of the outer layer portion 220 during bending.

The graphite sheets 232 are not adhered to each other at the bent portions 228 and 229, and are adhered to each other at two sides forming each of the connecting portions 224, which are unbent portions, and two sides forming each of the connecting portions 227. For this reason, the resistance of the bent portions 228 and 229 during bending can be reduced. The graphite sheets may be adapted not to be adhered to each other not only at the bent portions 228 and 229 but also at the other bent portions such as bent portions formed at corners between the first sheet portion 222 and the connecting portions 224 and bent portion formed at corners between the second sheet portion 226 and the connecting portions 227.

A plurality of pieces of the graphite 230O may be laminated and may then be collectively pouched with the resin film 231O. Similarly, a plurality of pieces of the graphite 230I may be laminated and may then be collectively pouched with the resin film 231I. In these cases, the graphite 230O and the graphite 230I are an example of a “thermally conductive layer” according to the technique of the present disclosure.

### Fourth Embodiment

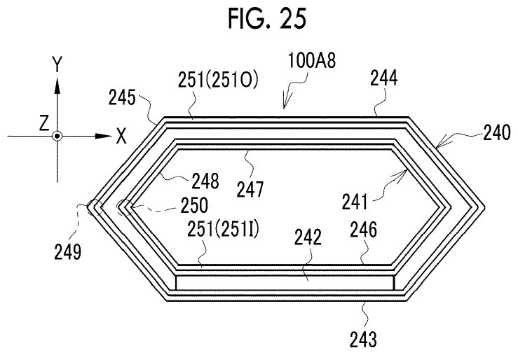

For example, as shown in FIG. 25, a thermally conductive member 100A8 of a fourth embodiment includes an outer layer portion 240 and an inner layer portion 241 disposed inside the outer layer portion 240 (in a space surrounded by the outer layer portion 240). Both the outer layer portion 240 and the inner layer portion 241 have a hexagonal shape as viewed in the Z-axis direction. The outer layer portion 240 and the inner layer portion 241 are connected to each other via a connecting portion 242.

The outer layer portion 240 includes a first sheet portion 243, a second sheet portion 244 that has the same length as the first sheet portion 243 and faces the first sheet portion 243, and a pair of V-shaped connecting portions 245 that connects the first sheet portion 243 and the second sheet portion 244. Similarly, the inner layer portion 241 includes a first sheet portion 246, a second sheet portion 247 that has the same length as the first sheet portion 246 and faces the first sheet portion 246, and a pair of V-shaped connecting portions 248 that connects the first sheet portion 246 and the second sheet portion 247.

Each connecting portion 245 includes a bent portion 249, and each connecting portion 248 includes a bent portion 250. The bent portion 249 is a corner between two sides forming the connecting portion 245, and the bent portion 250 is a corner between two sides forming the connecting portion 248. Both the bent portions 249 and 250 protrude outward.

Two graphite sheets 251 are laminated, so that each of the outer layer portion 240 and the inner layer portion 241 is formed. The graphite sheet 251 forming the outer layer portion 240 and the graphite sheet 251 forming the inner layer portion 241 have the same thickness and density of graphite included therein unlike the graphite sheets 232O and 232I of the third embodiment. However, in the following description, for the convenience of description, the graphite sheet 251 forming the outer layer portion 240 is referred to as a graphite sheet 251O and the graphite sheet 251 forming the inner layer portion 241 is referred to as a graphite sheet 251I such that the graphite sheets 251 are distinguished from each other. The graphite sheet 251 is an example of a “thermally conductive layer” according to the technique of the present disclosure.

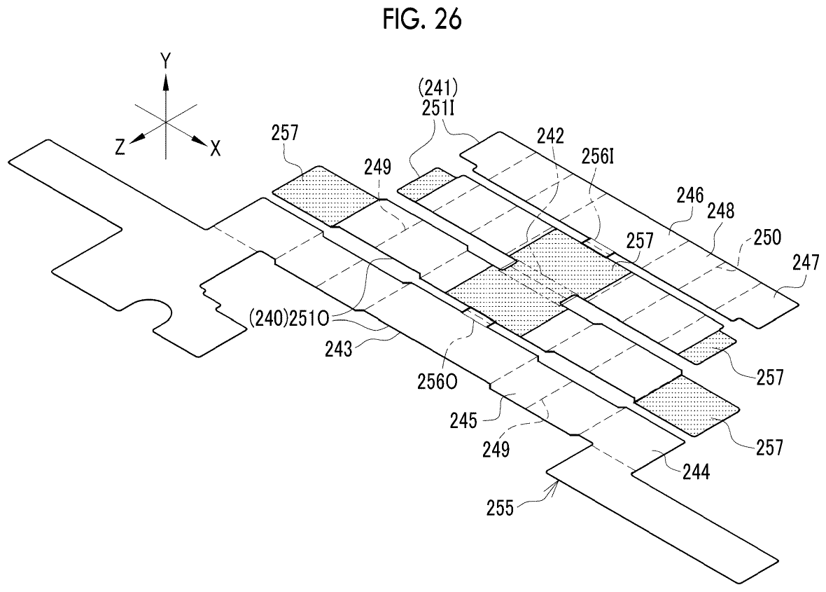

For example, as shown in FIG. 26, a thermally conductive member 100A8 is formed of one sheet-like material 255. The material 255 includes two graphite sheets 251O forming the outer layer portion 240 and two graphite sheets 251I forming the inner layer portion 241. The two graphite sheets 251O are connected to each other by one connecting portion 256O. Further, the two graphite sheets 251I are connected to each other by one connecting portion 256I. In the following description, the connecting portions 256O and 256I may be collectively referred to as a connecting portion 256.

The connecting portion 256O is provided at a central portion of the graphite sheets 251O that is a portion serving as the first sheet portion 243 of the outer layer portion 240. That is, the connecting portion 256O is provided at a portion other than the bent portions 249. The first sheet portion 243 is an example of an “unbent portion” according to the technique of the present disclosure.

The connecting portion 256I is provided at a central portion of the graphite sheets 251I that is a portion serving as the first sheet portion 246 of the inner layer portion 241. That is, the connecting portion 256I is provided at a portion other than the bent portions 250. The first sheet portion 246 is an example of an “unbent portion” according to the technique of the present disclosure.

A double-sided adhesive tape 257 is attached to portions, which serve as the first sheet portion 243 and the second sheet portion 244, of the graphite sheet 251O, which is close to the connecting portion 242, of the two graphite sheets 251O. Further, the double-sided adhesive tape 257 is attached to portions, which serve as the first sheet portion 246 and the second sheet portion 247, of the graphite sheet 251I, which is close to the connecting portion 242, of the two graphite sheets 251I.

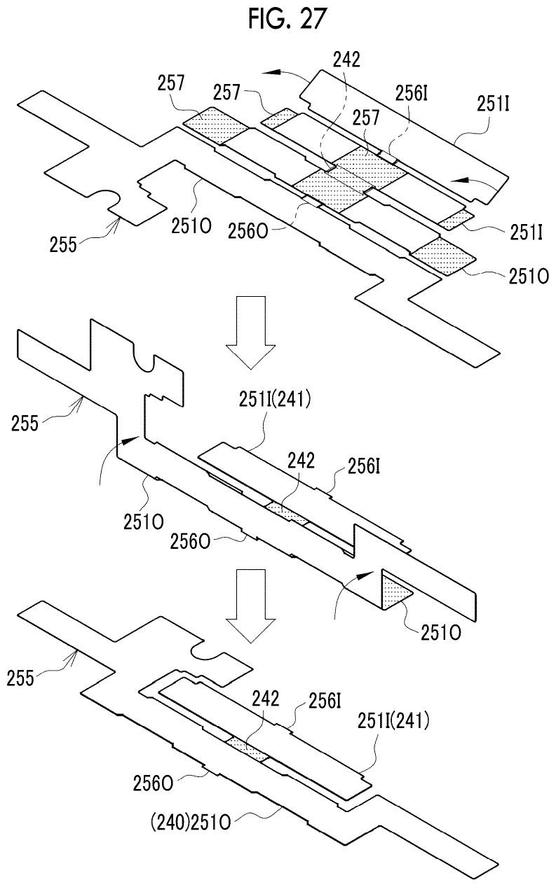

For example, broken line portions of the material 255 shown in FIG. 26 are bent as shown in FIG. 27, so that the thermally conductive member 100A8 is formed. Specifically, first, as shown in an upper portion and a middle portion, a portion corresponding to the connecting portion 256I is bent by an angle of 180°, so that the two graphite sheets 251I are caused to face each other. Then, the two graphite sheets 251I are overlapped and adhered to each other by an adhesive of the double-sided adhesive tape 257. Next, as shown in the middle portion and a lower portion, a portion corresponding to the connecting portion 256O is bent by an angle of 180°, so that the two graphite sheets 251O are caused to face each other. Then, the two graphite sheets 251O are overlapped and adhered to each other by the adhesive of the double-sided adhesive tape 257. After that, a portion corresponding to the connecting portion 242 is bent by an angle of 180°, so that a portion serving as the outer layer portion 240 and a portion serving as the inner layer portion 241 are caused to face each other. Then, after portions corresponding to the bent portions 250 and the like are bent to form the inner layer portion 241, portions corresponding to the bent portions 249 and the like are bent to form the outer layer portion 240.

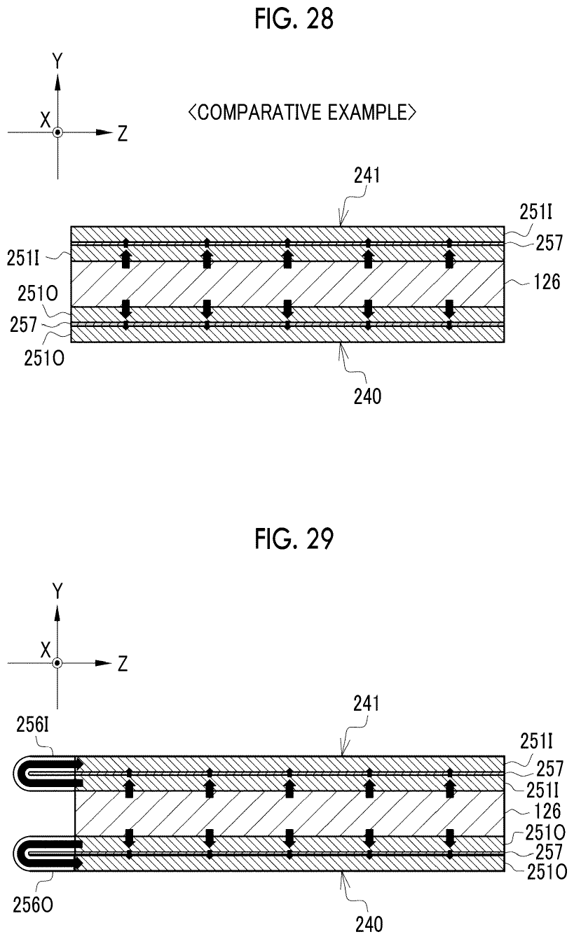

For example, a case where connecting portions 256O and 256I are not provided and only a plurality of graphite sheets 251O and 251I are simply laminated as shown in FIG. 28 is considered as a comparative example. In this case, the heat of the imaging element 16 is more conducted to the first graphite sheets 251O and 251I that are in contact with the second piece 126 of the thermally conductive member 100B. However, the heat is not conducted to the second graphite sheets 251O and 251I, which are not in contact with the second piece 126, from the first graphite sheets 251O and 251I so much. For this reason, an effect to be obtained in a case where the plurality of graphite sheets 251 are laminated cannot be sufficiently exhibited. Further, in this case, a conduction path of the heat of the imaging element 16 is cut off in a case where the adhesive force of the double-sided adhesive tape 257 is weakened and the two adjacent graphite sheets 251 are peeled off.

On the other hand, for example, as shown in FIG. 29, in the thermally conductive member 100A8 of the fourth embodiment, a plurality of graphite sheets 251 are laminated, two adjacent graphite sheets 251 among the plurality of graphite sheets 251 are connected to each other by the connecting portion 256, and the graphite sheets 251 are laminated by being bent at the connecting portion 256. For this reason, heat is conducted to the second graphite sheets 251O and 251I, which are not in contact with the second piece 126, from the first graphite sheets 251O and 251I, which are in contact with the second piece 126, via the connecting portions 256O and 256I. Therefore, an effect to be obtained in a case where the plurality of graphite sheets 251 are laminated can be sufficiently exhibited, so that the thermal conductivity of the thermally conductive member 100A8 can be further improved. Further, even though the adhesive force of the double-sided adhesive tape 257 is weakened and the two adjacent graphite sheets 251 are peeled off, the conduction path of the heat of the imaging element 16 can be ensured by the connecting portions 256O and 256I. Furthermore, even though the two adjacent graphite sheets 251 are peeled off, the two graphite sheets 251 can be prevented from being separated from each other by the connecting portions 256O and 256I.

The two adjacent graphite sheets 251 are adhered to each other by an adhesive of the double-sided adhesive tape 257. For this reason, heat conduction efficiency can be improved as compared to a case where the two adjacent graphite sheets 251 are not adhered to each other.

The connecting portion 256 is provided at an unbent portion other than the bent portions 249 and 250. For this reason, there is no concern that the bending of the bent portions 249 and 250 is hindered by the connecting portion 256.

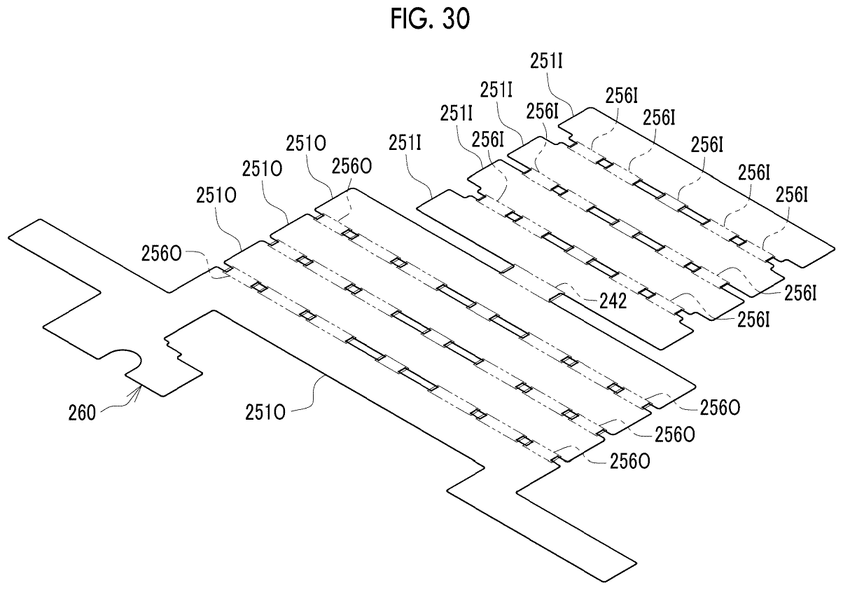

Although two has been exemplified as the number of laminated graphite sheets 251, the number of laminated graphite sheets 251 is not limited thereto. Further, although a case where one connecting portion 256 is provided has been exemplified, the present disclosure is not limited thereto. For example, as in a material 260 shown in FIG. 30, the number of each of the graphite sheets 251O and 251I may be set to four and the number of each of the connecting portions 256O and 256I may be set to five. Even in this case, the connecting portions 256O and 256I are provided at portions other than the bent portions 249 and 250.

### Fifth Embodiment

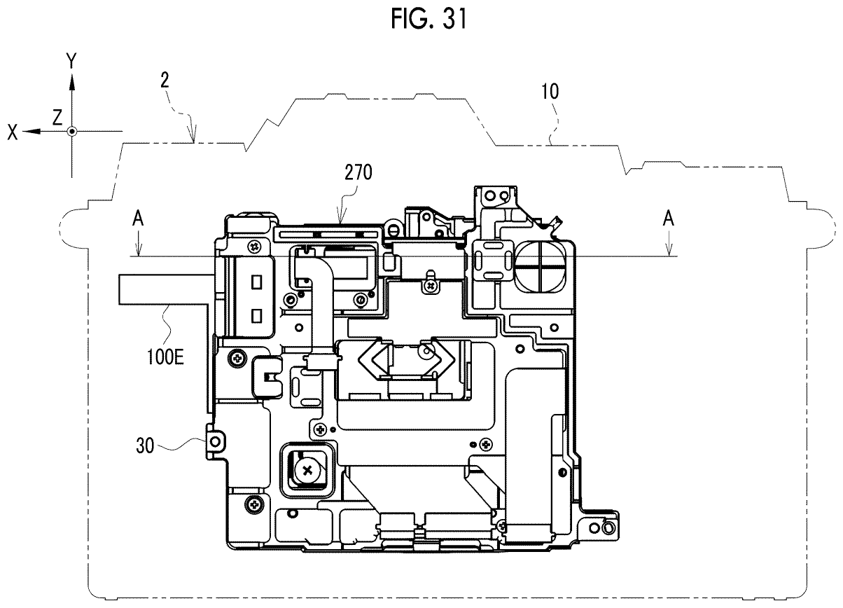

For example, as shown in FIG. 31, an imaging element unit 270 according to a fifth embodiment comprises a thermally conductive member 100E. The thermally conductive member 100E is connected to the stationary member 30 and the camera body 10. The thermally conductive member 100E is a metal plate, for example, a copper plate.

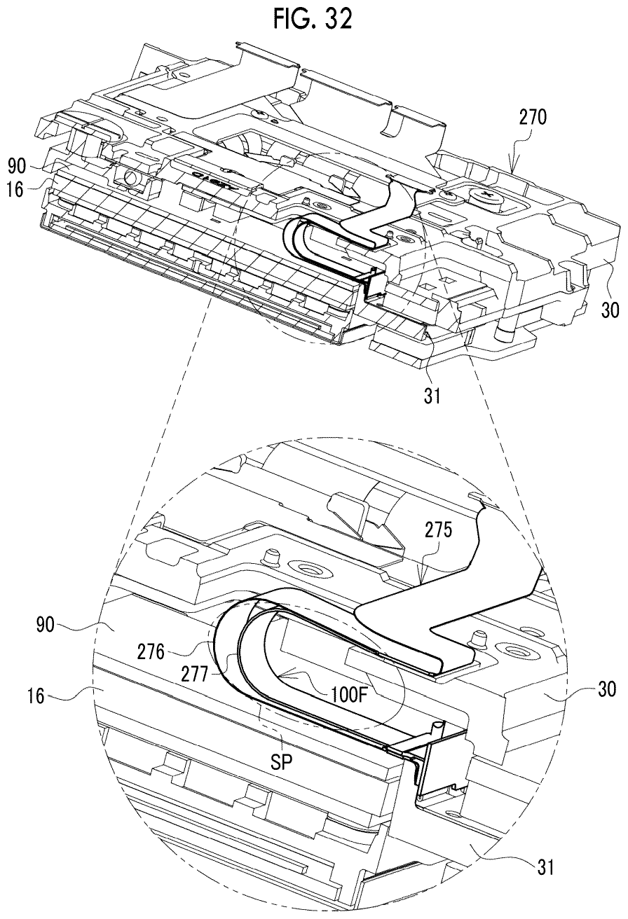

In FIG. 32 showing a cross-sectional view of the imaging element unit 270 taken along line A-A of FIG. 31, a flexible board 275 and a thermally conductive member 100F are connected to the stationary member 30 and the movable member 31. The flexible board 275 is connected to the imaging element 16 through the movable member 31. The flexible board 275 and the thermally conductive member 100F are disposed between the stationary member 30 and the movable member 31. The flexible board 275 includes a C-shaped flexural portion 276 that allows the movable member 31 to move. Similarly, the thermally conductive member 100F includes a C-shaped flexural portion 277 that allows the movable member 31 to move. The flexible board 275 and the thermally conductive member 100F are adhered to each other by a double-sided adhesive tape at portions other than the flexural portions 276 and 277.

The thermally conductive member 100F is disposed in a space SP that is formed by the flexural portion 276 of the flexible board 275. The thermally conductive member 100F is slightly smaller than the flexible board 275 not to hinder the movement of the flexible board 275, but substantially has a shape along the flexible board 275. The shape “along” the flexible board 275 includes not only a shape that completely matches the flexible board 275 but also a shape that substantially matches the flexible board 275 as in the case of the thermally conductive member 100F of FIG. 32.

The thermally conductive member 100F conducts heat of the imaging element 16, which is stored in the movable member 31, to the stationary member 30. The thermally conductive member 100F is formed of, for example, a graphite sheet as with the thermally conductive member 100A1 and the like. For this reason, the thermally conductive member 100F can be caused to have appropriate elasticity.

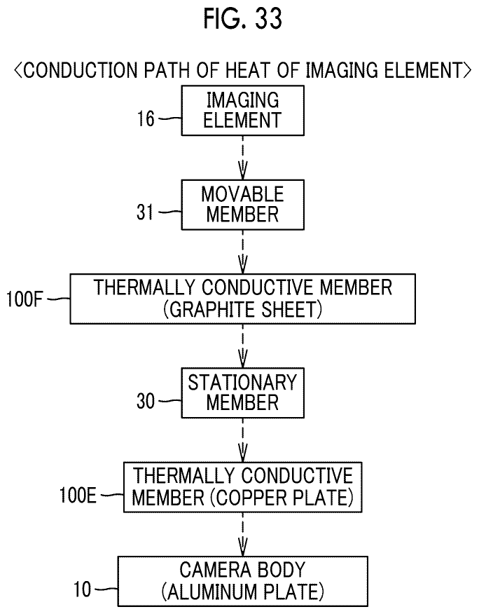

In the imaging element unit 270 according to the present embodiment, the heat of the imaging element 16 follows a conduction path shown in FIG. 33 as an example. That is, the heat of the imaging element 16 is conducted to the movable member 31 first. Next, the heat is conducted to the thermally conductive member 100F from the movable member 31. The heat conducted to the thermally conductive member 100F is conducted to the stationary member 30. The heat conducted to the stationary member 30 is conducted to the thermally conductive member 100E. In addition, the heat is conducted to the camera body 10 through the thermally conductive member 100E and is dissipated to the outside via the camera body 10.

As described above, in the fifth embodiment, the imaging element unit 270 comprises the thermally conductive member 100F that is connected to the stationary member 30 and the movable member 31, conducts the heat of the imaging element 16, which is stored in the movable member 31, to the stationary member 30, and includes the flexural portion 277 allowing the movable member 31 to move. For this reason, the heat of the imaging element 16 can be more efficiently dissipated.

The imaging element unit 270 comprises the flexible board 275 that is connected to the imaging element 16 and includes the flexural portion 276 allowing the movable member 31 to move. The thermally conductive member 100F is disposed in a space SP that is formed by the flexural portion 276 of the flexible board 275. For this reason, the space SP can be effectively utilized as a place in which the thermally conductive member 100F is disposed.

The thermally conductive member 100F has a shape along the flexible board 275. For this reason, the thermally conductive member 100F can be smoothly deformed to follow the deformation of the flexible board 275 that is caused by the movement of the movable member 31.

The stationary member 30 is connected to the camera body 10 via the thermally conductive member 100E. For this reason, the heat of the imaging element 16, which is conducted to the stationary member 30 via the thermally conductive member 100F, can be efficiently dissipated to the camera body 10.

### 6_1st Embodiment

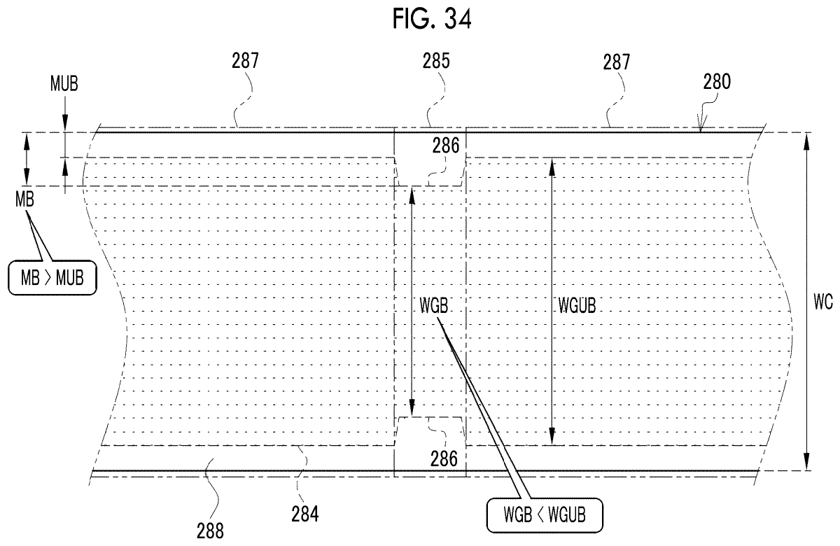

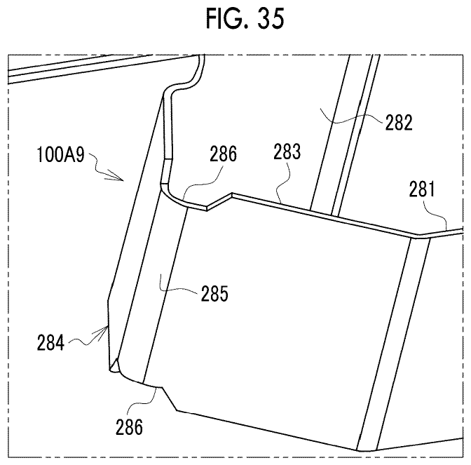

For example, as shown in FIG. 34, a structure of graphite 284 at V-shaped connecting portions 283 (see FIG. 35) connecting a first sheet portion 281 and a second sheet portion 282 is different in a graphite sheet 280 used to form a thermally conductive member 100A9 (see FIG. 35) of a 6_1st embodiment. Specifically, the graphite 284 includes recessed portions 286 recessed inward at a bent portion 285 that is a corner between two sides forming each of the connecting portions 283. For this reason, in the graphite 284, a width WGB of the bent portion 285 is smaller than a width WGUB of each of unbent portions 287 forming two sides of each of the connecting portions 283 (WGB<WGUB). On the other hand, a resin film 288 has the same width WC at the bent portion 285 and the unbent portion 287. Here, the term “the same” of the same width includes not only the meaning of “completely the same” but also the meaning of “substantially the same” that includes an error allowed in design and manufacturing, for example, an error of about ±10% of a design value. The graphite 284 is an example of a “thermally conductive material” according to the technique of the present disclosure, and the resin film 288 is an example of a “coating material” according to the technique of the present disclosure.

Since the graphite 284 includes the recessed portions 286 at each bent portion 285, a coating margin of the graphite 284, which is coated with the resin film 288, corresponding to a width MB at the bent portion 285 is larger than that corresponding to a width MUB at the unbent portion 287 (MB>MUB). For this reason, the bent portion 285 has a structure of which mechanical strength is higher than that of the unbent portion 287. Here, the coating margin is a distance between an end portion of the graphite 284 in a width direction and an end portion of the resin film 288 in the width direction.

FIG. 35 is a perspective view of the thermally conductive member 100A9 after assembly. The resin film 288 is not shown in FIG. 35 to avoid complication.

As described above, in the 6_1st embodiment, the bent portion 285 has a structure of which mechanical strength is higher than that of the unbent portion 287. For this reason, damage to the resin film 288, which is a coating material, can be suppressed at the bent portions 285 that are deformed many times to follow the movement of the imaging element 16, and, by extension, the durability of the thermally conductive member 100A9 can be improved.

The graphite sheet 280 includes the graphite 284 and the resin film 288 that coats the graphite 284 and is wider than the graphite 284. The coating margin, which is a distance between the end portion of the graphite 284 in the width direction and the end portion of the resin film 288 in the width direction, is larger at the bent portion 285 than at the unbent portion 287. Specifically, the width of the graphite 284 is smaller at the bent portion 285 than at the unbent portion 287. Moreover, the width of the resin film 288 is the same at the bent portion 285 and the unbent portion 287. For this reason, it is possible to reduce a concern that the resin film 288 may be damaged at the bent portion 285 and the graphite 284 may leak out to the outside, and it is possible to easily increase the mechanical strength of the bent portion 285. In addition, special processing does not need to be performed on the resin film 288, and an inexpensive resin film 288 can be used.

### 6_2nd Embodiment

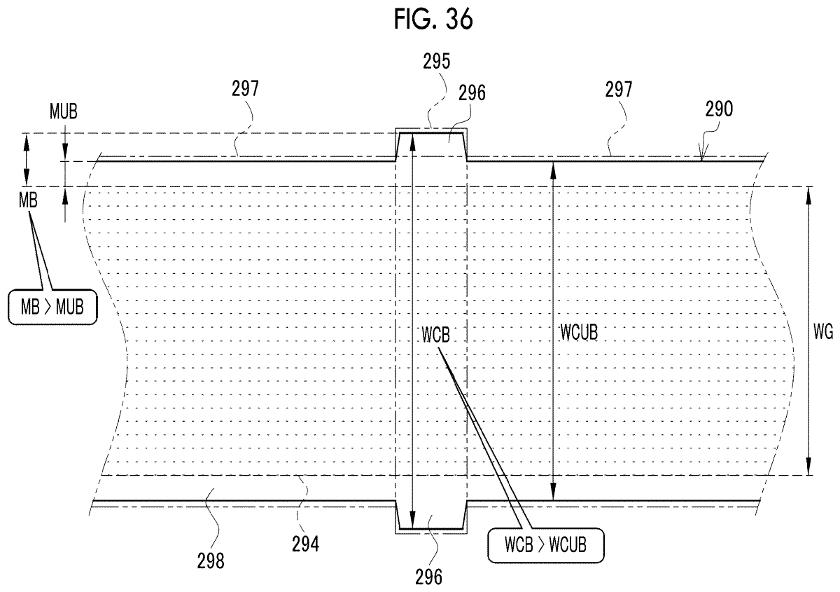

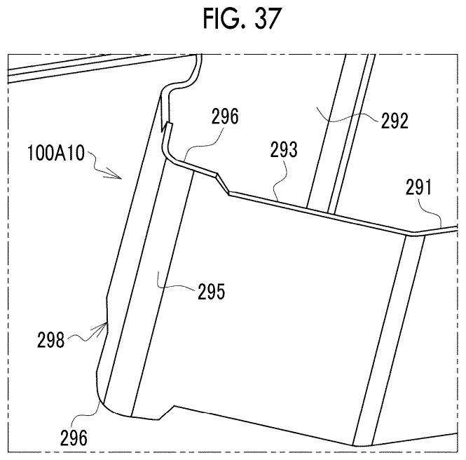

For example, as shown in FIG. 36, a structure of a resin film 298 at V-shaped connecting portions 293 (see FIG. 37) connecting a first sheet portion 291 and a second sheet portion 292 is different in a graphite sheet 290 used to form a thermally conductive member 100A10 (see FIG. 37) of a 6_2nd embodiment. Specifically, the resin film 298 includes protruding portions 296 protruding outward at a bent portion 295 that is a corner between two sides forming each of the connecting portions 293. For this reason, a width WCB of the bent portion 295 is larger than a width WCUB of an unbent portion 297 forming two sides each of the connecting portions 293 in the resin film 298 (WCB>WCUB). On the other hand, graphite 294 has the same width WG at the bent portion 295 and the unbent portion 297. Here, the term “the same” of the same width includes not only the meaning of “completely the same” but also the meaning of “substantially the same” that includes an error allowed in design and manufacturing, for example, an error of about ±10% of a design value. The graphite 294 is an example of a “thermally conductive material” according to the technique of the present disclosure, and the resin film 298 is an example of a “coating material” according to the technique of the present disclosure.

Since the resin film 298 includes the protruding portions 296 at each bent portion 295, a coating margin of the graphite 294, which is coated with the resin film 298, corresponding to a width MB at the bent portion 295 is larger than that corresponding to a width MUB at the unbent portion 297 as in the case of the 6_1st embodiment (MB>MUB). For this reason, the bent portion 295 has a structure of which mechanical strength is higher than that of the unbent portion 297. Here, the coating margin is a distance between an end portion of the graphite 294 in a width direction and an end portion of the resin film 298 in the width direction, as in the case of the 6_1st embodiment.

FIG. 37 is a perspective view of the thermally conductive member 100A10 after assembly. The graphite 294 is not shown in FIG. 37 to avoid complication.

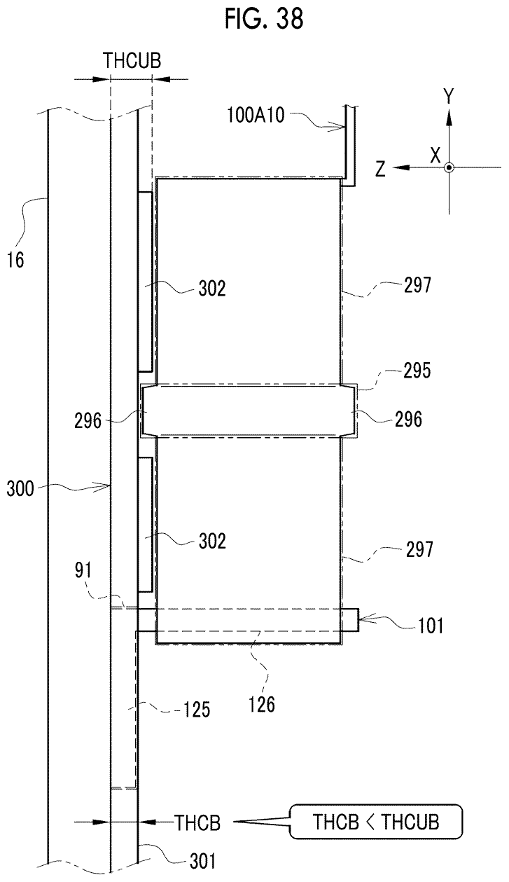

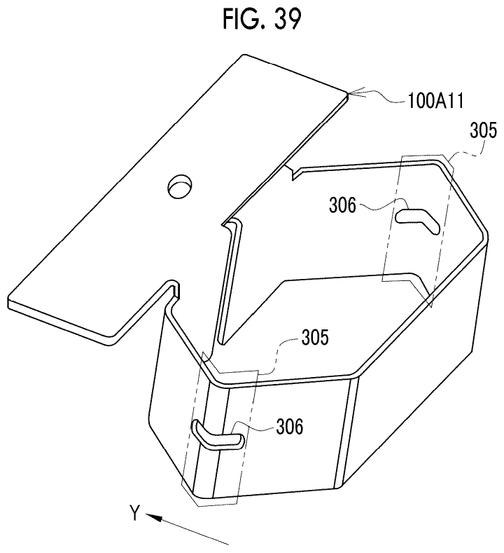

For example, as shown in FIG. 38, a plurality of mounting components 302 are mounted on a back surface 301 of a circuit board 300 of the present embodiment. The mounting component 302 is, for example, a control circuit, a drive circuit, a power source circuit, a resistor, or a capacitor for the imaging element 16, or the like. The mounting components 302 are mounted at positions facing the unbent portions 297 of the thermally conductive member 100A10, but are not mounted at positions facing the bent portions 295. For this reason, the thickness THCB of the circuit board 300, which includes the mounting components 302, at a position facing the bent portion 295 is smaller than the thickness THCUB thereof at a position facing the unbent portion 297 (THCB<THCUB).

Even in the 6_2nd embodiment, the bent portion 295 has a structure of which mechanical strength is higher than that of the unbent portion 297. For this reason, the durability of the bent portions 295 that are deformed many times to follow the movement of the imaging element 16, and, by extension, the durability of the thermally conductive member 100A10 can be improved.

Further, in the 6_2nd embodiment, a width of the resin film 298 is larger at the bent portion 295 than at the unbent portion 297. Moreover, the width of the graphite 294 is the same at the bent portion 295 and the unbent portion 297. For this reason, it is possible to reduce a concern that the resin film 298 may be damaged at the bent portion 295 and the graphite 294 may leak out to the outside, and it is possible to easily increase the mechanical strength of the bent portion 295. In addition, special processing does not need to be performed on the graphite 294, and inexpensive graphite 294 can be used.

The thermally conductive member 100A10 is disposed at a position facing the circuit board 300 of the imaging element 16. The thickness THCB of the circuit board 300 at a position facing the bent portion 295 is smaller than the thickness THCUB thereof at a position facing the unbent portion 297. For this reason, it is possible to reduce a concern that the mounting components 302 of the circuit board 300 may interfere with the bent portions 295 and hinder the bending of the bent portions 295. Further, a space between the thermally conductive member 100A10 and the circuit board 300, which is formed by the protruding portions 296, can be effectively utilized as a place in which the mounting components 302 are mounted. In a case where the thickness THCB of the circuit board 300 at a position facing the bent portion 295 is smaller than the thickness THCUB thereof at a position facing the unbent portion 297 and the mounting components 302 do not interfere with the bent portions 295, the mounting components 302 may be mounted at positions facing the bent portions 295.

### Seventh Embodiment

For example, as shown in FIG. 39, a slit 306 is formed at each bent portion 305 in a thermally conductive member 100A11 of a seventh embodiment. A longitudinal direction of the slit 306 is along a Y-axis direction that is a direction in which the thermally conductive member 100A11 expands and contracts due to the bending of the bent portion 305.

As described above, the slit 306 is formed at each bent portion 305 in the seventh embodiment. For this reason, the resistance of the bent portion 305 during bending can be reduced. The thermally conductive member 100A11 can be smoothly deformed to follow the movement of the imaging element 16 caused by the anti-vibration function. Therefore, a movable load of the thermally conductive member 100A11 can be reduced.

The longitudinal direction of the slit 306 is along the Y-axis direction that is a direction in which the thermally conductive member 100A11 expands and contracts due to the bending of the bent portion 305. For this reason, a wide conduction path of the heat of the imaging element 16 in the Y-axis direction can be ensured as compared to a case where the longitudinal direction of the slit 306 is along a direction intersecting the Y-axis direction, for example, a Z-axis direction or the like. A reduction in the heat conduction efficiency of the thermally conductive member 100A11 caused by the formation of the slits 306 can be suppressed as much as possible.

The slit 306 may be formed at a bent portion formed at a corner between the first sheet portion and the connecting portion and a bent portion formed at a corner between the second sheet portion and the connecting portion.

The CPU 18 has been exemplified as a processor that controls the operation of the imaging element unit 15, but the processor is not limited thereto. A programmable logic device (PLD) that is a processor of which the circuit configuration can be changed after manufacture, such as a field programmable gate array (FPGA), a dedicated electrical circuit that has a circuit configuration designed exclusively to perform specific processing, such as an application specific integrated circuit (ASIC), and/or the like may be used instead of or in addition to the CPU 18.

The plates 45 to 47 are provided on the stationary member 30 and the recessed portions 70 to 72 are provided on the movable member 31 in the first embodiment, but the present disclosure is not limited thereto. The plates 45 to 47 may be provided on the movable member 31, and the recessed portions 70 to 72 may be provided on the stationary member 30. Further, the magnets 40 to 42 are provided on the stationary member 30 and the coils 60 to 62 are provided on the movable member 31 in the first embodiment, but the present disclosure is not limited thereto. The magnets 40 to 42 may be provided on the movable member 31 and the coils 60 to 62 may be provided on the stationary member 30.

The number of sets of the balls 35 to 37, the plates 45 to 47, and the recessed portions 70 to 72 is not limited to three and may be four or more.

The imaging element unit according to the embodiment of the present disclosure can also be applied to an imaging apparatus other than the exemplified digital camera 2, for example, a smartphone, a tablet terminal, a monitoring camera, or the like.

From the above description, it is possible to ascertain techniques described in the following supplementary claims.

[Supplementary claim 1]

An imaging element unit that is built in a housing of an imaging apparatus, the imaging element unit comprising:
an imaging element that includes an imaging surface for imaging a subject;
an anti-vibration function to move the imaging element in plane directions of the imaging surface; and
a thermally conductive member to which heat of the imaging element is conducted and which includes a bent portion to be deformed to be capable of following movement of the imaging element caused by the anti-vibration function and an unbent portion other than the bent portion,
wherein structures of the bent portion and the unbent portion are different from each other.
   [Supplementary claim 2]

The imaging element unit according to supplementary claim 1,
wherein the bent portion has a structure of which mechanical strength is higher than mechanical strength of the unbent portion.
   [Supplementary claim 3]

The imaging element unit according to supplementary claim 1 or 2,
wherein the thermally conductive member includes a thermally conductive material and a coating material that coats the thermally conductive material and is wider than the thermally conductive material, and
a coating margin, which is a distance between an end portion of the thermally conductive material in a width direction and an end portion of the coating material in the width direction, is larger at the bent portion than at the unbent portion.
   [Supplementary claim 4]

The imaging element unit according to supplementary claim 3,
wherein a width of the thermally conductive material is smaller at the bent portion than at the unbent portion.
   [Supplementary claim 5]

The imaging element unit according to supplementary claim 4,
wherein a width of the coating material is the same at the bent portion and the unbent portion.
   [Supplementary claim 6]

The imaging element unit according to supplementary claim 3,
wherein a width of the coating material is larger at the bent portion than at the unbent portion.
   [Supplementary claim 7]

The imaging element unit according to supplementary claim 6,
wherein a width of the thermally conductive material is the same at the bent portion and the unbent portion.
   [Supplementary claim 8]

The imaging element unit according to supplementary claim 6 or 7,
wherein the thermally conductive member is disposed at a position facing a circuit board of the imaging element, and
a thickness of the circuit board at a position facing the bent portion is smaller than a thickness of the circuit board at a position facing the unbent portion.
   [Supplementary claim 9]

The imaging element unit according to any one of supplementary claims 1 to 8,
wherein the bent portion has a structure that reduces resistance to bending. [Supplementary claim 10]

The imaging element unit according to any one of supplementary claims 1 to 9,
wherein a slit is formed at the bent portion.
   [Supplementary claim 11]

The imaging element unit according to supplementary claim 10,
wherein a longitudinal direction of the slit is along a direction in which the thermally conductive member expands and contracts due to bending of the bent portion.
   [Supplementary claim 12]

The imaging element unit according to any one of supplementary claims 1 to 11,
wherein thermally conductive layers including a thermally conductive material are laminated in the thermally conductive member, and
the thermally conductive layers are not adhered to each other at the bent portion and are adhered to each other at the unbent portion.
   [Supplementary claim 13]

The imaging element unit according to any one of supplementary claims 1 to 12,
wherein the bent portion is thinner than the unbent portion.
   [Supplementary claim 14]

The imaging element unit according to supplementary claim 13,
wherein at least the bent portion includes thermally conductive layers including a thermally conductive material,
thermally conductive layers including a thermally conductive material are laminated in at least the unbent portion, and
the number of the thermally conductive layers laminated in the unbent portion is larger than the number of the thermally conductive layers laminated in the bent portion.
   [Supplementary claim 15]

An imaging apparatus comprising:
a housing; and
the imaging element unit according to any one of supplementary claims 1 to 14 that is built in the housing.

Various embodiments and/or various modification examples described above can also be appropriately combined in the technique of the present disclosure. Further, it is natural that the present disclosure is not limited to each embodiment described above and may employ various configurations without departing from the scope.

The above-described contents and illustrated contents are detailed descriptions for parts according to the disclosed technique and are merely an example of the disclosed technique. For example, the description of the configuration, functions, actions, and effects having been described above is the description of examples of the configuration, functions, actions, and effects of the portions according to the technique of the present disclosure. Accordingly, it goes without saying that unnecessary portions may be deleted or new elements may be added or replaced in the description contents and shown contents described above without departing from the scope of the technique of the present disclosure. In addition, particularly, description related to common technical knowledge or the like that does not need to be described in terms of embodying the disclosed technique is omitted in the above-described contents and the illustrated contents in order to avoid complication and to facilitate understanding of the parts according to the disclosed technique.

In this specification, “A and/or B” is synonymous with “at least one of A or B”. That is, “A and/or B” may mean only A, may mean only B, or may mean a combination of A and B. In addition, in this specification, the same approach as “A and/or B” is applied to a case where three or more matters are represented by connecting the matters with “and/or”.

All documents, patent applications, and technical standards described in this specification are incorporated in this specification by reference to the same extent as in a case where each of the documents, the patent applications, and the technical standards are specifically and individually indicated to be built by reference.

What is claimed is:

1. An imaging element unit that is built in a housing of an imaging apparatus, the imaging element unit comprising:
an imaging element that includes an imaging surface for imaging a subject;
an anti-vibration function to move the imaging element in plane directions of the imaging surface; and
a thermally conductive member to which heat of the imaging element is conducted and which includes a bent portion to be deformed to be capable of following movement of the imaging element caused by the anti-vibration function and an unbent portion other than the bent portion,
wherein structures of the bent portion and the unbent portion are different from each other,
the thermally conductive member includes a thermally conductive material and a coating material that coats the thermally conductive material and is wider than the thermally conductive material, and
a coating margin, which is a distance between an end portion of the thermally conductive material in a width direction and an end portion of the coating material in the width direction, is larger at the bent portion than at the unbent portion.

2. An imaging element unit that is built in a housing of an imaging apparatus, the imaging element unit comprising:
an imaging element that includes an imaging surface for imaging a subject;
an anti-vibration function to move the imaging element in plane directions of the imaging surface; and
a thermally conductive member to which heat of the imaging element is conducted and which includes a bent portion to be deformed to be capable of following movement of the imaging element caused by the anti-vibration function and an unbent portion other than the bent portion,
wherein structures of the bent portion and the unbent portion are different from each other,
the thermally conductive member includes a thermally conductive material and a coating material that coats the thermally conductive material and is wider than the thermally conductive material, and
a width of the thermally conductive material is smaller at the bent portion than at the unbent portion.

3. An imaging element unit that is built in a housing of an imaging apparatus, the imaging element unit comprising:
an imaging element that includes an imaging surface for imaging a subject;
an anti-vibration function to move the imaging element in plane directions of the imaging surface; and
a thermally conductive member to which heat of the imaging element is conducted and which includes a bent portion to be deformed to be capable of following movement of the imaging element caused by the anti-vibration function and an unbent portion other than the bent portion,
wherein structures of the bent portion and the unbent portion are different from each other,
the bent portion is thinner than the unbent portion.

4. The imaging element unit according to claim 1,
wherein the bent portion has a structure of which mechanical strength is higher than mechanical strength of the unbent portion.

5. The imaging element unit according to claim 2,
wherein the bent portion has a structure of which mechanical strength is higher than mechanical strength of the unbent portion.

6. The imaging element unit according to claim 3,
wherein the bent portion has a structure of which mechanical strength is higher than mechanical strength of the unbent portion.

7. The imaging element unit according to claim 2,
wherein a width of the coating material is the same at the bent portion and the unbent portion.

8. The imaging element unit according to claim 1,
wherein a width of the coating material is larger at the bent portion than at the unbent portion.

9. The imaging element unit according to claim 8,
wherein a width of the thermally conductive material is the same at the bent portion and the unbent portion.

10. The imaging element unit according to claim 8,
wherein the thermally conductive member is disposed at a position facing a circuit board of the imaging element, and
a thickness of the circuit board at a position facing the bent portion is smaller than a thickness of the circuit board at a position facing the unbent portion.

11. The imaging element unit according to claim 1,
wherein the bent portion has a structure that reduces resistance to bending.

12. The imaging element unit according to claim 2,
wherein the bent portion has a structure that reduces resistance to bending.

13. The imaging element unit according to claim 3,
wherein the bent portion has a structure that reduces resistance to bending.

14. The imaging element unit according to claim 1,
wherein a slit is formed at the bent portion.

15. The imaging element unit according to claim 2,
wherein a slit is formed at the bent portion.

16. The imaging element unit according to claim 3,
wherein a slit is formed at the bent portion.

17. The imaging element unit according to claim 14,
wherein a longitudinal direction of the slit is along a direction in which the thermally conductive member expands and contracts due to bending of the bent portion.

18. The imaging element unit according to claim 15,
wherein a longitudinal direction of the slit is along a direction in which the thermally conductive member expands and contracts due to bending of the bent portion.

19. The imaging element unit according to claim 16,
wherein a longitudinal direction of the slit is along a direction in which the thermally conductive member expands and contracts due to bending of the bent portion.

20. The imaging element unit according to claim 1,
wherein thermally conductive layers including a thermally conductive material are laminated in the thermally conductive member, and
the thermally conductive layers are not adhered to each other at the bent portion and are adhered to each other at the unbent portion.

21. The imaging element unit according to claim 2,
wherein thermally conductive layers including a thermally conductive material are laminated in the thermally conductive member, and
the thermally conductive layers are not adhered to each other at the bent portion and are adhered to each other at the unbent portion.

22. The imaging element unit according to claim 3,
wherein thermally conductive layers including a thermally conductive material are laminated in the thermally conductive member, and
the thermally conductive layers are not adhered to each other at the bent portion and are adhered to each other at the unbent portion.

23. The imaging element unit according to claim 3,
wherein at least the bent portion includes thermally conductive layers including a thermally conductive material,
thermally conductive layers including a thermally conductive material are laminated in at least the unbent portion, and
the number of the thermally conductive layers laminated in the unbent portion is larger than the number of the thermally conductive layers laminated in the bent portion.

24. An imaging apparatus comprising:
a housing; and
the imaging element unit according to claim 1 that is built in the housing.

25. An imaging apparatus comprising:
a housing; and
the imaging element unit according to claim 2 that is built in the housing.

26. An imaging apparatus comprising:
a housing; and
the imaging element unit according to claim 3 that is built in the housing.
